(19) United States
(12) Patent Application Publication
(10) Pub. No.: US 2025/0125213 A1
(43) Pub. Date: Apr. 17, 2025

(54) Integrated Circuit with Anisotropic Thermal Dissipation Structure

(71) Applicant: Taiwan Semiconductor Manufacturing Company, Ltd., Hsin-Chu (TW)

(72) Inventor: Hung-Kun LO, New Taipei City (TW)

(21) Appl. No.: 18/589,129

(22) Filed: Feb. 27, 2024

Related U.S. Application Data
(60) Provisional application No. 63/589,398, filed on Oct. 11, 2023.

(51) Int. Cl. H01L 23/373; H01L 23/29; H01L 25/065; H01L 27/02; H01L 27/088

(52) U.S. Cl. CPC H01L 23/3733; H01L 23/293; H01L 25/0655; H10D 84/834; H10D 89/931

(57) ABSTRACT

The present disclosure provides an integrated circuit (IC) structure that includes a first substrate with a first surface having a normal direction along a first direction; a first IC chip bonded to the first substrate; and a second IC chip electrically connected to the first IC chip. The first and second IC chips are sealed in a same package having a sealing material layer, and the sealing material layer includes a first anisotropic thermal dissipation material. The first anisotropic thermal dissipation material is thermally conductive with a first thermal conductivity along the first direction and a second thermal conductivity along a second direction being perpendicular to the first direction. The second thermal conductivity is substantially greater than the first thermal conductivity.

### PRIORITY DATA

This application claims priority to U.S. Provisional Patent Application Ser. No. 63/589,398 filed on Oct. 11, 2023, the entire disclosure of which is hereby incorporated herein by reference.

### BACKGROUND

Many of the technological advances have occurred in the field of a three-dimensional IC (3DIC) packaging, which involves stacking and bonding multiple chips together. Each chip includes at least one functional IC, such as an IC configured to perform a logic function, a memory function, a digital function, an analog function, a mixed signal function, a radio frequency (RF) function, a input/output (I/O) function, a communications function (e.g., provides support for wired communications and/or wireless communications by implementing desired communication protocols, such as 5G (i.e., 5th generation) wireless communications protocols, Ethernet communications protocols, IB communications protocols, etc.), a power management function, other function, or combinations thereof. memory devices, and some of these involve capacitors. With continued advances in 3DIC stacking technology, integrated chips may experience various issues including thermal dissipation issue, which may further cause other issues, such as bonding, stressing and delamination issues.

On other aspects, as multi-gate devices are used for advanced IC structures and continue to scale, challenges have arisen in some areas including current leakage and thermal dissipation issue, especially when the IC structures have high current, and high voltage or high speed.

Therefore, while existing 3DIC structures (or advanced IC structures), and the method making the same are generally adequate for their intended purposes, they are not satisfactory in all aspects.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion. It is also emphasized that the drawings appended illustrate only typical embodiments of this invention and are therefore not to be considered limiting in scope, for the invention may apply equally well to other embodiments.

FIGS. 1, 2A-2E illustrate schematic views of an anisotropic thermal dissipation polymer material according to various embodiments.

FIGS. 3A and 3B illustrate schematic views of an anisotropic thermal dissipation liquid crystal material according to various embodiments.

FIG. 4 is a flowchart of a method to form an anisotropic thermal dissipation liquid crystal material on a substrate according to various aspects of the present disclosure.

FIGS. 4A-4E illustrate cross-sectional views of an IC structure with an anisotropic thermal dissipation liquid crystal material at various intermediate stages of fabrication according to some embodiments.

FIG. 5 illustrates a cross-sectional view of an integrated circuit (IC) structure, according to various aspects of the present disclosure.

FIGS. 6A-6B illustrate a flowchart of a method to form the IC structure of FIG. 5, in portion or in entirety, according to various aspects of the present disclosure.

FIGS. 7-14 illustrate cross-sectional views of an IC structure at various intermediate stages of fabrication and processed in accordance with the method of FIGS. 6A-6B according to an embodiment of the present disclosure.

FIG. 15 is a flowchart of a method to form the IC structure, in portion or in entirety, according to various aspects of the present disclosure.

FIGS. 16-19 illustrate cross-sectional views of an IC structure at various intermediate stages of fabrication and processed in accordance with the method of FIG. 15 according to an embodiment of the present disclosure.

FIG. 20 is a flowchart of a method to form the IC structure of FIG. 15, in portion or in entirety, according to various aspects of the present disclosure.

FIGS. 21-23 illustrate cross-sectional views of an IC structure at various intermediate stages of fabrication and processed in accordance with the method of FIG. 20 according to an embodiment of the present disclosure.

FIGS. 24-27 illustrate cross-sectional views of an IC structure constructed according to various embodiments.

FIGS. 28-29 illustrate cross-sectional views of an IC structure constructed according to various embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

The present disclosure relates to an integrated circuit (IC) structure and a method of making the same, more specifically a complimentary field-effect transistor (CFET) device having a directional thermal dissipation structure. The present disclosure also relates to methods and structures directed to an IC structure having advanced packaging structure, such as a three-dimensional IC (3DIC) structure, and a method making the same. The 3DIC structures are stacked structures with heterogenous integration, for example having logic devices stacked over memory devices, or vice versa. In the disclosed embodiments, the IC structure includes a transistor structure having multiple vertically stacked transistors, each of which includes multiple vertically stacked nanowires or nanosheets as channels, and a gate structure wrapping around each of the channels. More specifically, the IC structure includes a complementary field-effect transistor (CFET) structure and the method of making the CFET. The CFET may include N-type FETs vertically over P-type FETs or P-type FETs vertically over the N-type FET.

The disclosed IC structure and the method making the same are related to an integrated circuit structure having multi-gate devices, especially a CFET structure and/or a 3DIC structure integrated with a thermal dissipation structure having an anisotropic heat dissipation material. The disclosed IC structure includes various features, materials, and configurations to enhance directional heat dissipation. The disclosed IC structure and the method making the same provide more efficient heat dissipation and prevent heat from flowing to less thermally stable structure.

The disclosed IC structure and the method making the same are collectively described in detail according to various embodiments.

In some embodiments, the IC structure includes a carrier substrate bonded to a semiconductor substrate having integrated circuits formed thereon, such as a FET with multiple channels vertically stacked, such as a CFET. A thermal dissipation structure is further formed on a backside of the semiconductor substrate to provide thermal dissipation. It is understood that the provided structures are only some embodiments, and the IC structure may include more than two semiconductor structures bonded together with similar bonding structures. The IC structure includes a thermal dissipation structure of an anisotropic thermal dissipation material (ATDM) layer for directional thermal dissipation.

An ATDM layer is a thermal material with anisotropic thermal characteristics. Particularly, the thermal conductivity of the ATDM is different along different directions due to the anisotropic thermal characteristics of the ATDM. In ATDM, the thermal conductivity along a certain direction (referred to as thermal direction) is substantially greater than the thermal conductivity along other directions. In some embodiments, the thermal conductivity along the thermal direction is greater than 0.5 W/m·K and the thermal conductivity along other directions is less than 0.1 W/m·K. This thermal characteristics of the ATDM is incorporated into the IC structure to direct the heat along certain direction and avoid the heat flowing to undesired direction and region, therefore more effectively dissipating the thermal energy generated in the IC structure, maintaining the IC structure in low temperature, and enhancing the performance and reliability of the IC structure.

In some embodiments, the ATDM is electrically insulating (or dielectric) and thermally conductive so that it will properly dissipate heat without interfering with electrical routing.

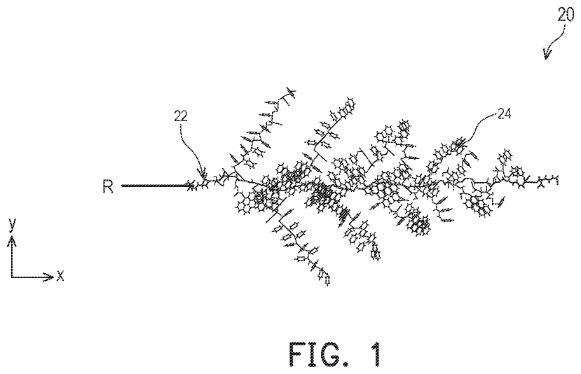

In some embodiments, the ATDM is a tapered bottlebrush polymer 20, as illustrated in FIG. 1A. FIG. 1A is a schematic view of a tapered bottlebrush polymer 20, constructed according to some embodiments. The tapered bottlebrush polymer 20 has a tree-like structure with a main stem 22 along x direction and branches 24 extended from the main stem 22. The branches 24 are oriented along a tilted direction. Accordingly, the tapered bottlebrush polymer 20 has an anisotropic structure, especially with different characteristics along X direction and −X direction, leading to different thermal behaviors along X direction and −X direction. With the structure of the tapered bottlebrush polymer 20 illustrated in FIG. 1A, it is found through experiments and simulations that the thermal conductivity along −X direction is substantially greater than the thermal conductivity along X direction. Thus, the heat flows dominantly along −X direction relative to X direction. In some embodiments, the main stem 22 of the tapered bottlebrush polymer 20 is further chemically bonded with a chemical group R. In some embodiments, the chemical group R includes an organic functional group, such as an alkyl group with hydrogen attached to hydrocarbons, may have a straight, branched, or cyclic structure, and may further include hetero atoms, such as containing nitrogen or oxygen atoms. In some embodiments, the chemical group R includes at least one of an alkyl group, a fluoro group, and a benzyl group. In some embodiments, the chemical group R includes at least one of a carboxylic group, hydroxyl group, a thiol group, an enol group, a phenol group, a sulfonyl acid group, and/or a SO₂OH group. The inorganic acid may include perchloric acid, hydrogen iodide, hydrogen bromide, hydrogen chloride, nitric acid, thiocyanic acid, chloric acid, iodic acid, hypophosphorous acid, hydrogen fluoride, nitrous acid, cyanic acid, hydrazoic acid, hypochlorous acid, hypobromous acid, hydrocyanic acid, hypoiodous acid, sulfuric acid, chromic acid, sulfurous acid, phosphoric acid, phosphorous acid, pyrophosphoric acid, carbonic acid, hydrogen sulfide, and/or boric acid.

The tapered bottlebrush polymer 20 is attached to an IC structure (such as IC structure 250 or 280 described later) through chemical bonding. In the disclosed embodiments, the IC structure includes a dielectric surface layer and the tapered bottlebrush polymer 20 is bonded to the dielectric surface of the IC structure. In furtherance of the embodiments, the IC structure includes a dielectric surface layer of a dielectric material, such as silicon oxide (SiO₂), silicon nitride (SiN) or a silicon oxycarbonitride (SiOCN). The dielectric surface of the IC structure includes some chemical group intrinsically present or introduced by proper chemical treatment. Those chemical group can chemically react with the chemical group R of the tapered bottlebrush polymer 20, thereby forming chemical bonds and immobilizing the tapered bottlebrush polymer 20 on the IC structure with increased adhesion.

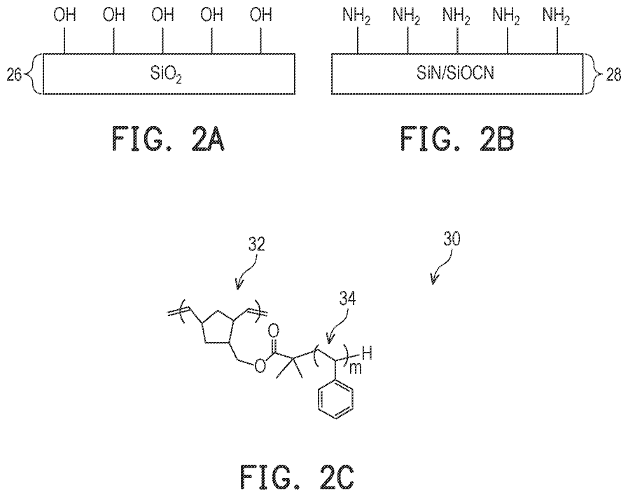

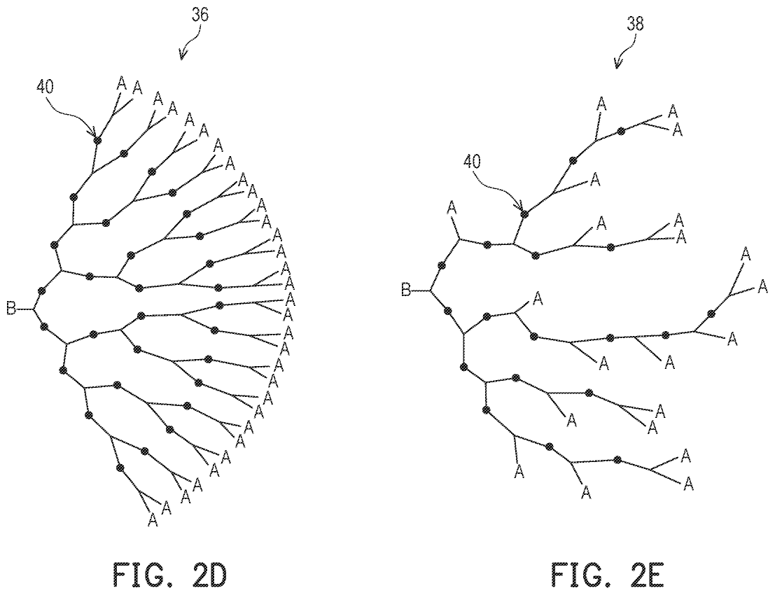

Referring to FIG. 2A, in some embodiments, the IC structure includes a dielectric surface layer 26 of silicon oxide having OH groups, which are intrinsically present on the surface. The OH groups on the dielectric surface layer 26 of silicon oxide chemically react with the chemical group R of the tapered bottlebrush polymer 20, thereby forming chemical bonds therebetween. In some embodiments, the dielectric surface layer 26 of silicon oxide is further treated to introduce OH groups to the dielectric surface layer 26 using a proper treatment, such as ozone or hydrogen peroxide treatment. For example, the IC structure is placed in an ozone or hydrogen peroxide environment with an elevated temperature for a certain duration.

Referring to FIG. 2B, in some embodiments, the IC structure includes a dielectric surface layer 28 of silicon nitride or silicon oxycarbonitride having NH₂ groups, which are intrinsically present on the surface. The NH₂ groups on the dielectric surface layer 28 of silicon nitride or silicon oxycarbonitride chemically react with the chemical group R of the tapered bottlebrush polymer 20, thereby forming chemical bonds therebetween.

In some embodiments, the tapered bottlebrush polymer 20 includes a chemical structure 30 as illustrated in FIG. 2C. The chemical structure 30 includes a polynorbornene 32 as the backbone and polystyrene 34 as the sidechain.

In some embodiments, the tapered bottlebrush polymer 20 includes a dendritic polymer structure, such as 36 and 38 illustrated in FIGS. 2D and 2E, respectively. Note that the polymers 36 and 38 are different in topologic structure. For example, the polymer 36 includes a regular structure with each node having two branches and each chain from the root to the tip have the same length. The polymer 38 includes an irregular structure with each node having one or two branches and each chain from the root to the tip have different lengths.

The polymer 36 or polymer 38 includes a chemical group 40 as nodes of the dendritic polymer structure; a chemical group B as the root of the dendritic polymer structure that can be immobilized on the material through reacting with surface amine or hydroxyl group; and a chemical group A as the terminals of the branches. In some embodiments, the chemical groups A, B and 40 are a same chemical group, such as carbon, oxygen, or nitrogen. In various embodiments, the chemical group 40 represents the linkers formed from coupling reaction of the chemical group A and B, and includes ether, ester, boric ester, peptide bonds; the chemical reaction pair group A/B includes acrylate/amine, boronic acids/alcohols, carboxylic acid/alcohol, among others. This polymer-based ATDM is also referred to as anisotropic thermal dissipation polymer (ATD-P).

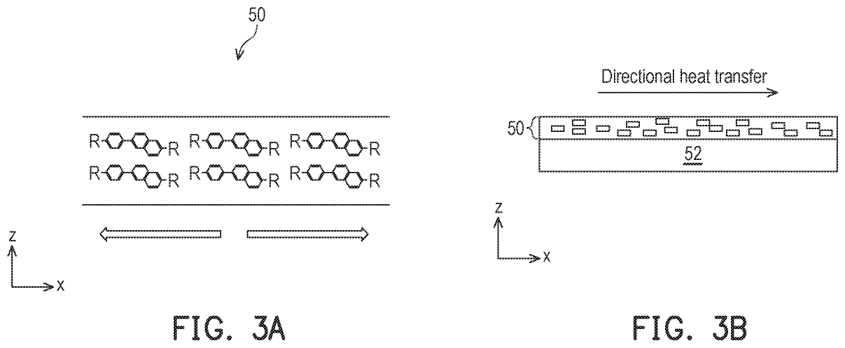

In some embodiments, the ATDM is a liquid crystal material layer or a material incorporating with a liquid crystal. as illustrated in FIG. 3A. FIG. 3A is a schematic view of a liquid crystal material layer 50, constructed according to some embodiments. The liquid crystal material layer 50 has an anisotropy chemical structure such as one illustrated in FIG. 3, or other suitable liquid crystal materials. A liquid crystal is a thermodynamic stable phase characterized by anisotropy of properties without the existence of a three-dimensional crystal lattice, generally lying in the temperature range between the solid and isotropic liquid phase, hence the term mesophase. In some embodiments, the liquid crystal material has some common characteristic features, including a rodlike molecular structure, rigidness of the long axis, and strong dipole and easily polarizable substituents.

Especially, the liquid crystal material layer 50 provides an anisotropic thermal conductivity. For example, thermal conductive conductivities along X direction (or −X direction) is substantially greater than thermal conductivity along Z direction (or −Z direction). More specifically, the thermal energy flows dominantly along X direction. This is further described with reference to FIG. 3B. The liquid crystal material layer 50 is formed to a substrate 52. The heat transportation is directional and is dominantly along X direction with substantially less or neglectable heat transportation along Z direction. This liquid crystal ATDM is also referred to as anisotropic thermal dissipation liquid crystal (ATD-LC).

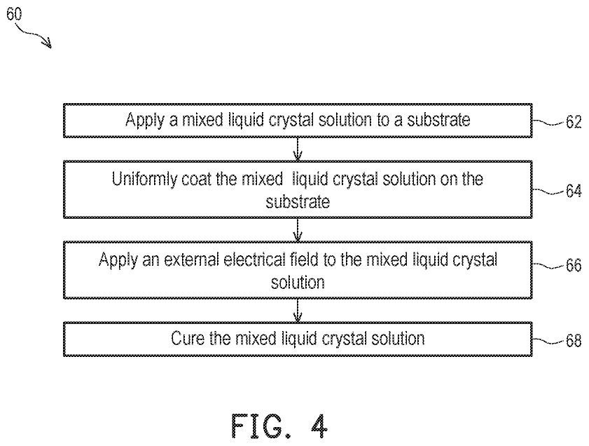

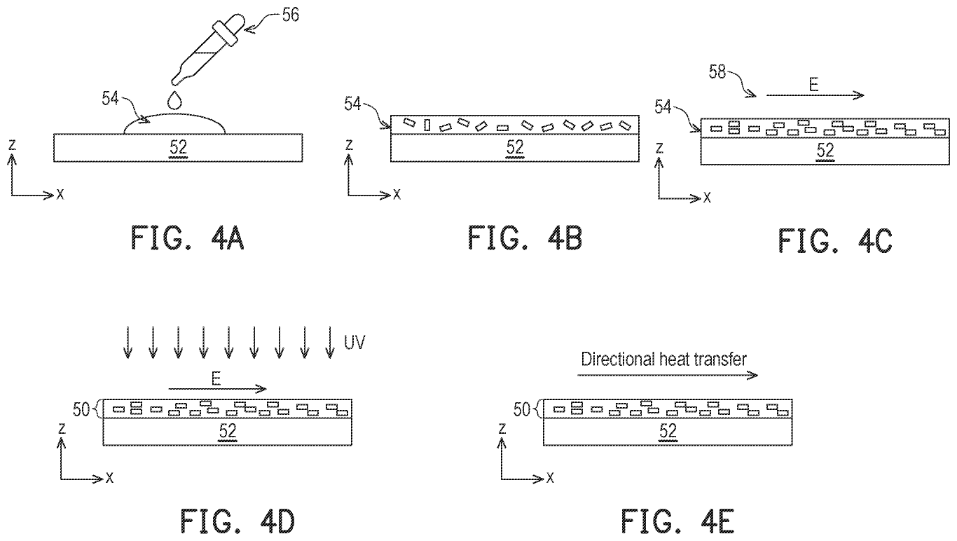

The method to form a liquid crystal material layer 50 on a substrate is further described with reference to FIGS. 4 and 4A through 4E. FIG. 4 is a flowchart of a method 60 forming an anisotropic thermal dissipation liquid crystal material on a substrate. FIGS. 4A through 4E are sectional views of an IC structure, in portion, constructed according to some embodiments.

Referring to FIGS. 4 and 4A, at an operation 62 of the method 60, a mixed liquid crystal solution 54 is applied to a substrate 52 by a suitable method, such as syringe 56 or other suitable technologies. In the disclosed embodiments, the mixed liquid crystal solution 54 is a mix of liquid crystal material and a photoresist material in solution. In some embodiments, the photoresist material includes a photosensitive chemical, such as chemical amplified photoresist (CAR). In some embodiments, the photoresist material may include a polymer material; a photoacid generator (PAG), which provides the solubility change to the developer; a solvent, and/or other suitable compositions. In some embodiments, the liquid crystal material includes any suitable liquid material such as a liquid crystal material 50 illustrated in FIG. 3A, cholesteryl benzoate molecule, or N-(4-methoxybenzylidene)-4-butylaniline (MBBA) molecule.

Referring to FIGS. 4 and 4B, at an operation 64 of the method 60, the mixed solution 54 is uniformly distributed to the top surface of the substrate 52 by a suitable method, such as spin-on coating, other suitable method or a combination thereof.

Referring to FIGS. 4 and 4C, at an operation 66 of the method 60, an external electrical field E is applied to the mixed solution to the mixed solution 54. The external electrical field E is configured in a direction such that the heat transportation is along the predesigned direction. In the present example, the external electrical field E is along X direction so that the director of the liquid crystal material in the mixed solution 54 aligns along an external field E, which is X direction.

Referring to FIGS. 4 and 4D, at an operation 68 of the method 60, a radiation such as ultraviolet (UV) radiation is applied to the mixed solution 54 to cure the mixed solution 54, thereby forming a liquid crystal material layer 50. Particularly, the external electrical field E remains when applying the UV radiation to the mixed solution 54. Thus, the liquid crystal material layer 50 is anisotropic and the heat transportation of the liquid crystal material layer 50 is directional and is dominantly along the predesigned direction. In the present example, the external electrical field E is along X direction so that the director of the liquid crystal material layer 50 aligns along an external field E, which is X direction, and the heat transportation of the liquid crystal material layer 50 is dominantly along X direction.

Referring to FIG. 4E, thus formed liquid crystal material layer 50 on the substrate 52 provides anisotropic thermal conductivity. More specifically, the thermal energy flows dominantly along X direction with substantially less or neglectable heat transportation along Z direction.

The present disclosure provides various anisotropic thermal dissipation materials, such as a liquid crystal material layer or a polymeric material layer with an anisotropic thermal conductivity, collectively referred to as anisotropic thermal dissipation material (AHDM). Those anisotropic thermal dissipation material can be applied to a semiconductor substrate with various IC devices formed thereon; or applied as a underfill material in a 3DIC packaging, which will be further described below with other figures.

In some embodiments, the disclosed IC structure includes a semiconductor substrate with CFETs formed thereon and with an anisotropic thermal dissipation material layer incorporated. The IC structure is formed by a proper procedure through various fabrication stages, such as a monolithic process. The monolithic process is described below according to some embodiments. The semiconductor stack of Si/SiGe is formed on the first substrate and is patterned to form fin active regions, dummy gate stacks are formed by deposition and patterning, the source/drain (S/D) regions are recessed by etch, the bottom gate isolation layer is formed, inner spacers are formed by deposition and etch, bottom S/D features are formed by epitaxial growth, bottom S/D isolation layer is formed, top S/D features are formed on the bottom S/D isolation layer, dummy gate is removed, the SiGe layers are removed by etch to release channels, the bottom metal gate stacks are formed to wrap around the bottom channels, the top metal gate stacks are formed to wrap around the top channels, self-aligned cap (SAC) is formed and interconnect structure is formed.

A second substrate (e.g., a carrier substrate) is bonded to the first substrate. The first substrate is thinned down from the backside and the anisotropic thermal dissipation material layer is formed on the backside of the first substrate. Other structures, such as backside vias and a backside interconnect structure, may be further formed on the anisotropic thermal dissipation material layer. Alternatively, backside vias and a backside interconnect structure are formed on the backside of the first substrate. Thereafter, the anisotropic thermal dissipation material layer is formed on the backside interconnect structure.

In some embodiments, the first substrate is a semiconductor substrate such as a silicon substrate while the second substrate is a semiconductor substrate or alternatively a dielectric substrate such as one of a silicon nitride substrate, a silicon oxide substrate, and an aluminum oxide substrate.

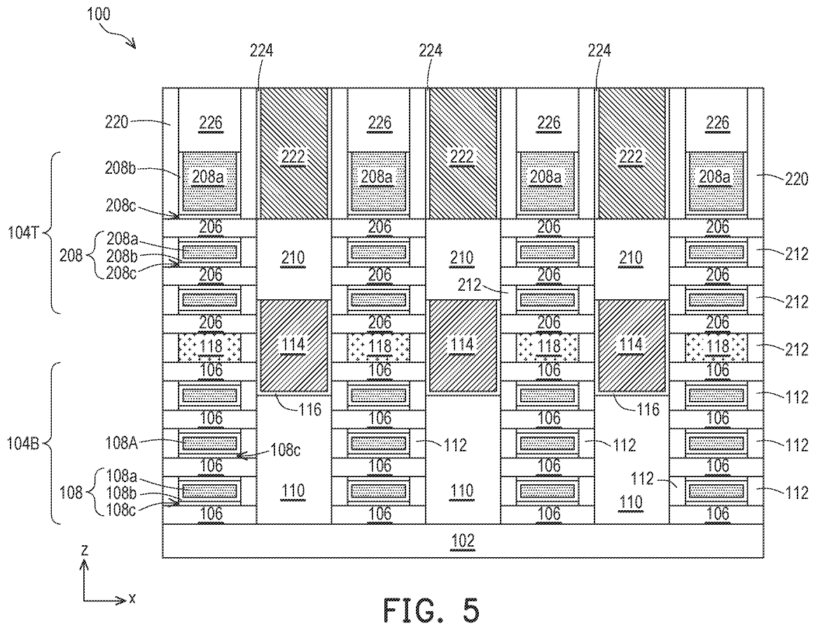

The IC structure with an anisotropic thermal dissipation material layer and the method making the same are further described below in detail. The IC structure formed by a monolithic process is described below according to some embodiments. FIG. 5 is a sectional view of an IC structure 100 having CFETs according to some embodiments.

Referring to FIG. 5, the IC structure 100 having CFETs is formed by a monolithic method. As an exemplary embodiment, FIG. 1 illustrates CFET devices formed a substrate 102, in which, an n-type FET (NFET) and a p-type FET (PFET) are vertically stacked on each other with reduced circuit area and improved device performance. A CFET device can be formed in any suitable procedure, such as monolithic process, sequential process, parallel process, other suitable process, or a combination thereof. Take the monolithic process as an example, In the monolithic process, both NFETs and PFETs are formed on the same substrate, such as NFET being formed first and PFET being formed thereafter on the same substrate 102.

The IC structure 100 includes various field effect transistors formed on the substrate 102, Each FET device has multiple channels vertically stacked, such as gate-all-around (GAA) structure. Especially bottom devices 104B (such as PFETs), and top devices 104T (such as NFETs) are vertically stacked on each other.

More specifically, the bottom devices 104B of the IC structure 100 include multiple channels 106; gate stacks 108 wrapping around the channel 106; and source/drain (S/D) features 110 disposed on both sides of the channels 106 and connecting to the vertically stacked channels 106. The bottom devices 104B also includes inner spacers 112 interposed between the gate stacks 108 and the S/D features 110 to provide isolation therebetween. The inner spacers 112 include one or more dielectric material, such as silicon oxide, silicon nitride, other suitable dielectric material or a combination thereof.

The gate stacks 108 further includes a gate dielectric layer 108b and a gate electrode 108a disposed on the gate dielectric layer. In the present embodiment, the gate dielectric layer 108b includes a high-k dielectric material and the gate electrode 108a includes metal or metal alloy. In some examples, the gate electrode 108a may include a number of sub-layers. The high-k dielectric material may include metal oxide, metal nitride, such as LaO, AlO, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTIO, (Ba,Sr)TiO₃ (BST), Al₂O₃, Si₃N₄, oxynitrides (SiON), or other suitable dielectric materials. The gate electrode 108a may include Ti, Ag, Al, TiAlN, TaC, TaCN, TaSIN, Mn, Zr, TiN, TaN, Ru, Mo, Al, WN, Cu, W, Ru, Co, any suitable conductive materials, or a combination thereof. In some embodiments, different metal materials are used for nFET and pFET devices with respective work functions to enhance device performance. In some embodiments, the gate stacks 108 may further include an interfacial layer 108c interposed between the channels 106 and the high-k dielectric material for improved integration. The interfacial layer 108c is a dielectric layer and may include silicon oxide.

Similarly, the top devices 104T of the IC structure 100 include multiple channels 206; gate stacks 208 wrapping around the channel 206; and source/drain (S/D) features 210 disposed on both sides of the channels 206 and connecting to the vertically stacked channels 206. The bottom devices 104B also includes inner spacers 212 interposed between the gate stacks 208 and the S/D features 210 to provide isolation therebetween. The inner spacers 212 include one or more dielectric material, such as silicon oxide, silicon nitride, other suitable dielectric material or a combination thereof.

The gate stacks 208 further includes a gate dielectric layer 208b and a gate electrode 208a disposed on the gate dielectric layer. In the present embodiment, the gate dielectric layer 208b includes a high-k dielectric material and the gate electrode 208a includes metal or metal alloy. In some examples, the gate electrode 208a may include a number of sub-layers. In some embodiments, different metal materials are used for nFET and pFET devices with respective work functions to enhance device performance. In some embodiments, the gate stacks 208 may further include an interfacial layer 208c interposed between the channels 206 and the high-k dielectric material for improved integration. The interfacial layer 208c may include silicon oxide.

The top devices 104T (such as NFETs) and the bottom devices 104B (such as PFETs) are vertically stacked and isolated from each other by isolation features, such as S/D isolation features 114 of one or more dielectric material, and gate isolation layer 118 of one or more dielectric material. In some embodiments, an etch stop layer 116 may be disposed to surround the S/D isolation feature 114 and includes different dielectric material to achieve etch selectivity.

The IC structure 100 further includes gate spacers 220 of one or more dielectric material disposed on sidewalls of the gate stacks 208; S/D contacts 222 of one or more conductive material landing on the S/D features 210 to couple the S/D features 210 to a power supply; and self-aligned cap (SAC) 226 of one or more dielectric material aligned to and landing on the gate stack 208. The S/D contacts 222 may be further surrounded by a barrier layer 224 of one or more dielectric material or alternative conductive material. In some examples, the barrier layer 224 includes conductive material(s), such as a titanium film and a titanium nitride film or tantalum film and a tantalum nitride film. In some other examples, the barrier layer 224 includes dielectric material(s), such as a silicon nitride, other suitable dielectric material or a combination thereof. In this case, the dielectric layer is deposited and is etched by plasma etching process so to remove the bottom portion of the barrier layer in order to have good electrical routing.

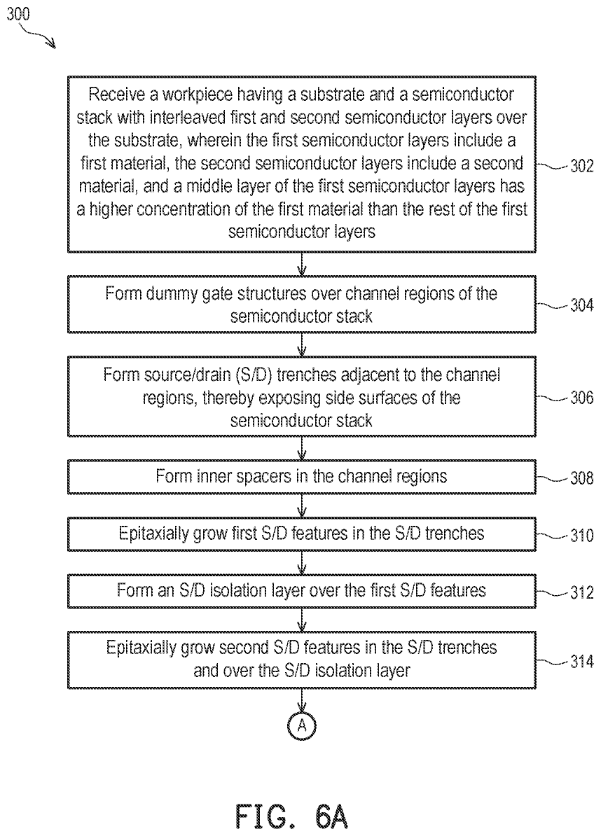

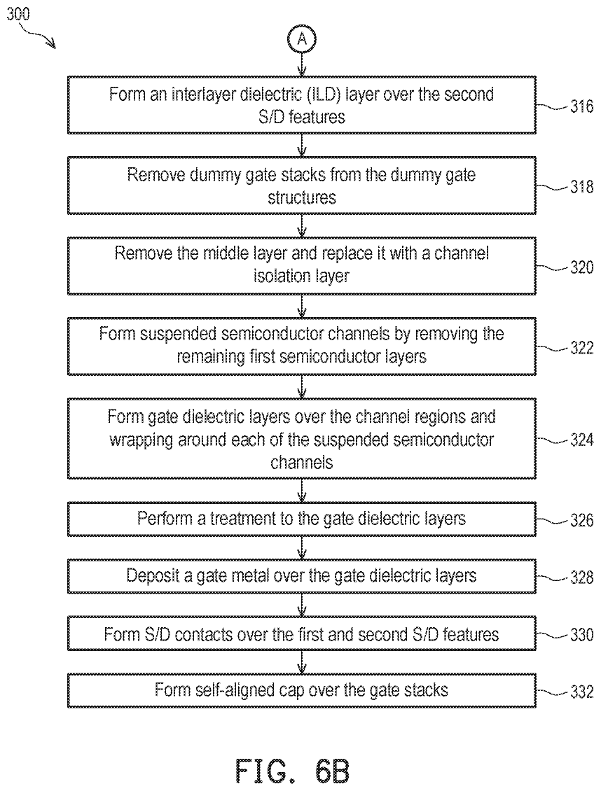

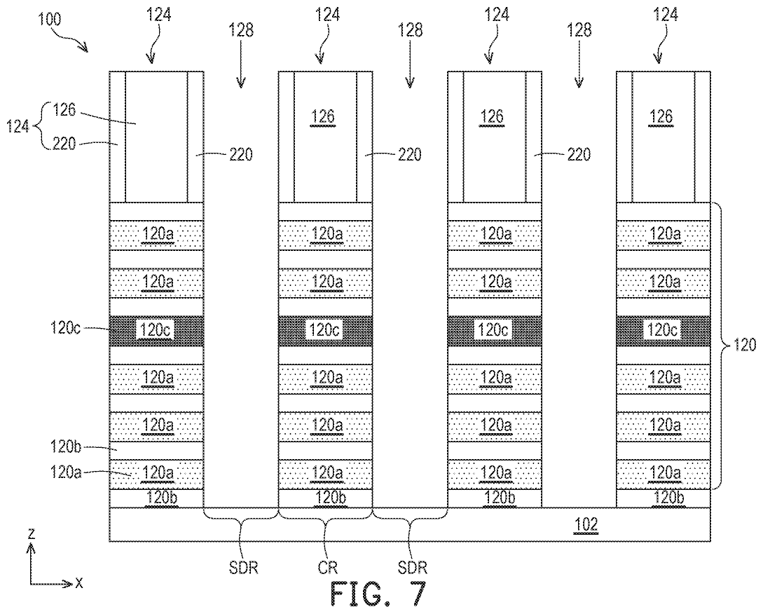

FIGS. 6A and 6B are a processing flowchart of a method 300 making the IC structure 100. FIGS. 7 through 15 are sectional views of the IC structure 100 at various fabrication stages according to some embodiments. The IC structure 100 and the method 300 are collectively described below with reference to those figures.

Referring to FIGS. 4A and 7, at operation 302, the method 300 receives or is provided with a workpiece having a substrate 102 and a semiconductor stack 120 with interleaved first and second semiconductor layers 120a, 120b over the substrate 102. The first semiconductor layers 120a include a first semiconductor material, the second semiconductor layers 120b include a second semiconductor material, and a middle layer 120c of the first semiconductor layers 120a has a higher concentration of the first semiconductor material than the rest of the first semiconductor layers 120a. The first and second semiconductor layers are patterned to form one or more semiconductor stack as active regions, such as fin active regions.

In the disclosed embodiments, the substrate 102 is a semiconductor substrate, such as a silicon substrate. In some other embodiments, the substrate 102 includes germanium, silicon germanium or other proper semiconductor materials. The substrate 102 may alternatively be made of some other suitable elementary semiconductor, such as diamond or germanium; a suitable compound semiconductor, such as silicon carbide, indium arsenide, or indium phosphide; or a suitable alloy semiconductor, such as silicon germanium carbide, gallium arsenic phosphide, or gallium indium phosphide.

In some embodiments, the first semiconductor material is silicon germanium, the second semiconductor is silicon, and the middle layer 120c include silicon germanium and has a high concentration of germanium than the rest of the first semiconductor layers 120a.

At operation 304, the method 300 forms dummy gate structures 124 over channel regions (CR) of the semiconductor stack 120. The dummy gate structures 124 include gate spacers 220 and dummy gate stacks 126. At operation 306, the method 300 forms source/drain (S/D) trenches 128 adjacent to the channel regions CR, thereby exposing side surfaces of the semiconductor stack 120.

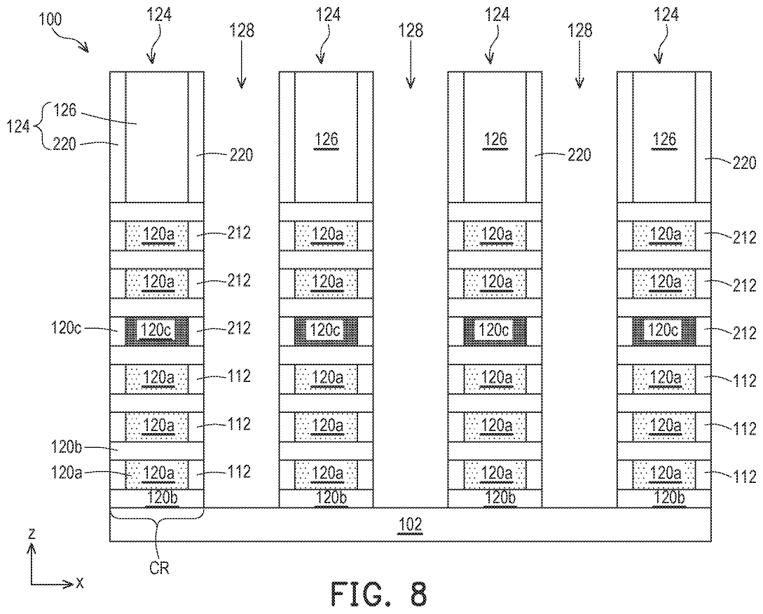

Referring to FIGS. 6A and 8, at operation 308, the method 300 form inner spacers 112 in the channel regions CR by a method such as a procedure that includes selective etch the first semiconductor layers 120a, depositing one or more dielectric material, and plasma etch.

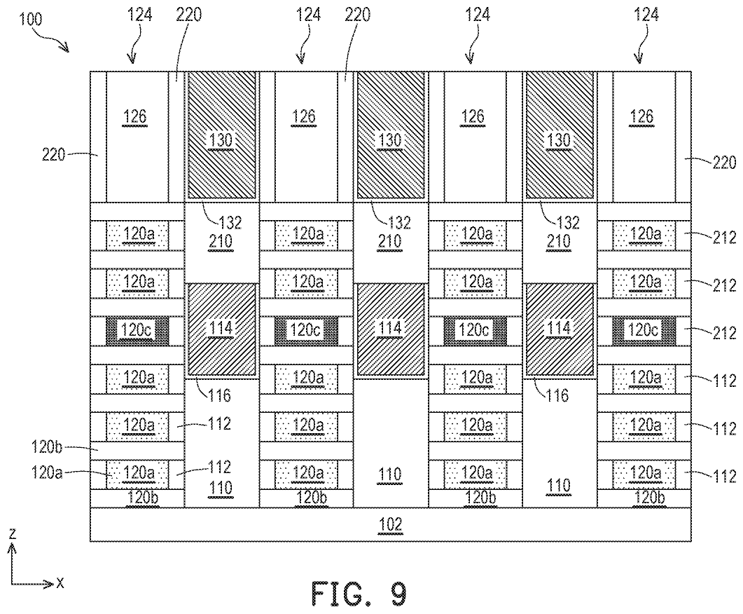

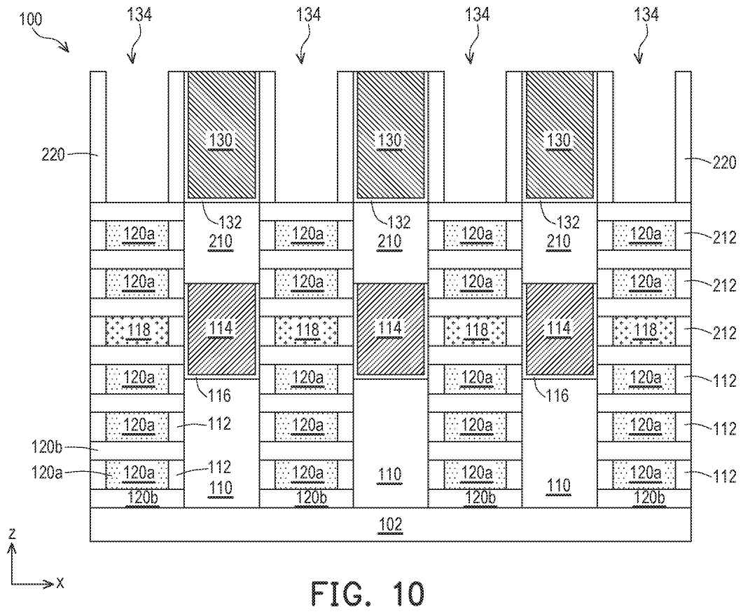

Referring to FIGS. 6A and 9, at operation 310, the method 300 epitaxially grows first S/D features 110 in the S/D trenches 128. At operation 312, the method 300 forms an S/D isolation layer 114, 116 over the first S/D features 110 by a method such as a procedure that includes depositing an etch stop layer 116, depositing a dielectric material layer 114, performing a chemical mechanical polishing (CMP) process, and etching back to recess the S/D isolation layer 114, 116.

Still referring to FIGS. 6A and 9, at operation 314, the method 300 epitaxially grows second S/D features 210 in the S/D trenches 128 and over the S/D isolation layer 114, 116.

Referring to FIGS. 6B and 9, at operation 316, the method 300 forms an interlayer dielectric (ILD) layer 130 over the second S/D features 210 by a method such as a procedure that includes deposition and CMP. The ILD structure may further include an etch stop layer 132 having a dielectric material different from the bulk dielectric material of the ILD layer 130 to achieve etch selectivity.

Referring to FIGS. 6B and 10, at operation 318, the method 300 removes dummy gate stacks 126 from the dummy gate structures 124, resulting in gate trenches 134. At operation 320, the method 300 removes the middle layer 120c and replaces it with a gate isolation layer 118.

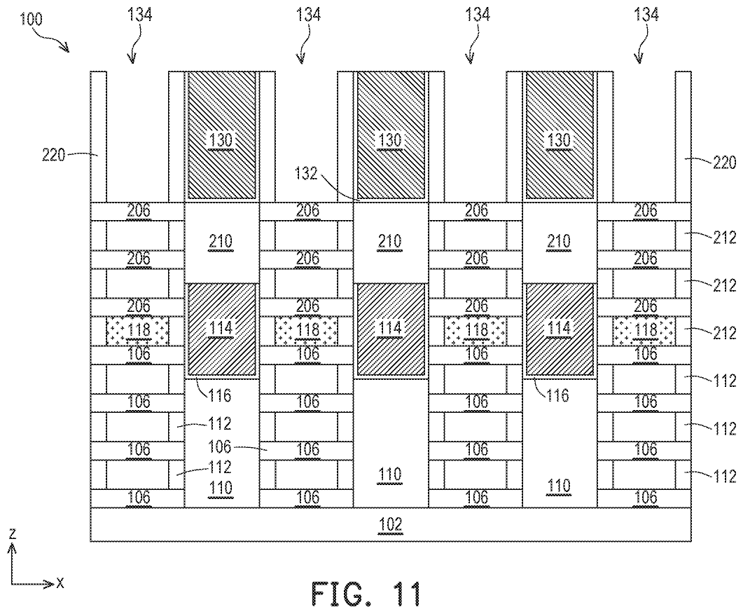

Referring to FIGS. 6B and 11, at operation 322, the method 300 forms suspended semiconductor channels 106, 206 by removing the remaining first semiconductor layers 120a and leaving the second semiconductor layers 120b as the suspended semiconductor channels 106, 206, respectively.

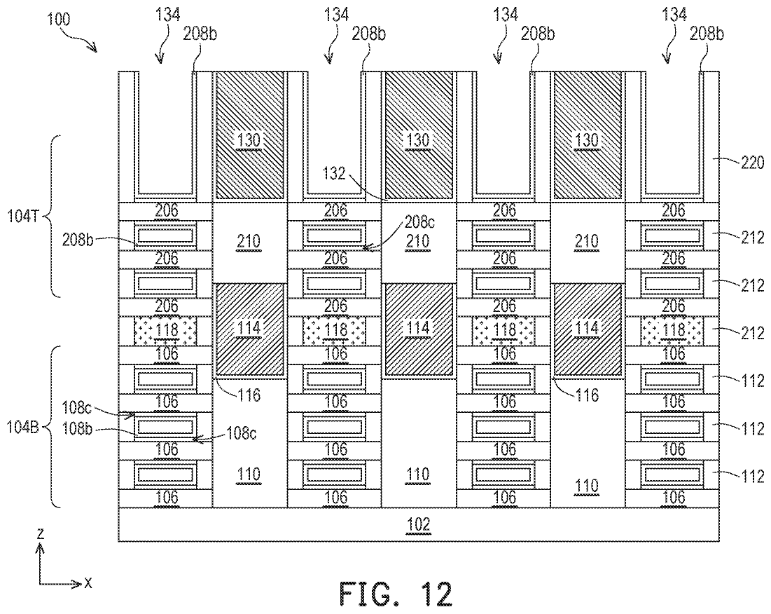

Referring to FIGS. 6B and 12, at operation 324, the method 300 forms gate dielectric layers (respectively referred to as 108b, 108c, and 208b, 208c) over the channel regions CR and wrapping around each of the suspended semiconductor channels 106, 206 or a subset thereof. Particularly, the dielectric layers 108c, 208c are interfacial layers; and the dielectric layers 108b, 208b are high-k dielectric material layers.

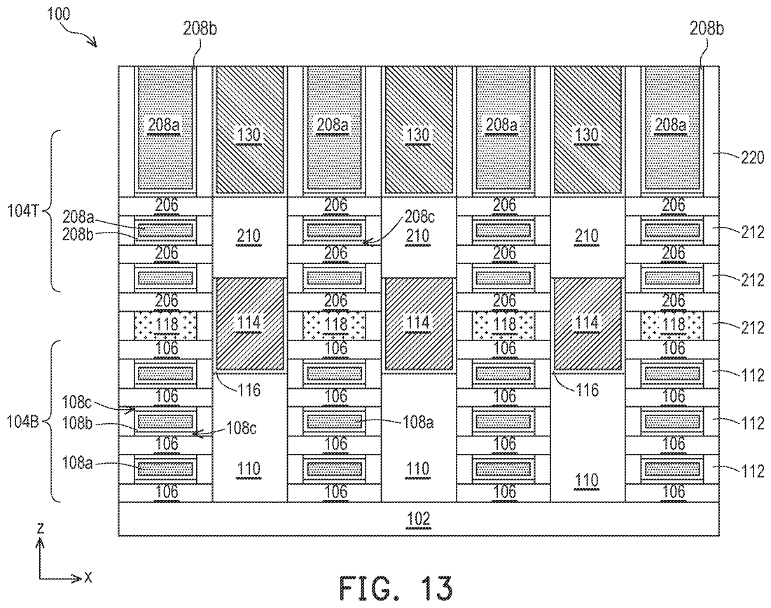

Referring to FIGS. 6B and 13, at operation 326, the method 300 may perform treatment, such as thermal annealing, to the gate dielectric layers. At operation 328, the method 300 deposits one or more gate electrode material (such as metal or metal alloy) over the gate dielectric layers. After forming the gate electrode 108a, 208a, metal gate structures 108, 208 are formed. The gate electrode may include one or more metal layers with different composition. Furthermore, the material(s) for the gate electrodes 108a and 208a may have different material(s) such as having different work function metals.

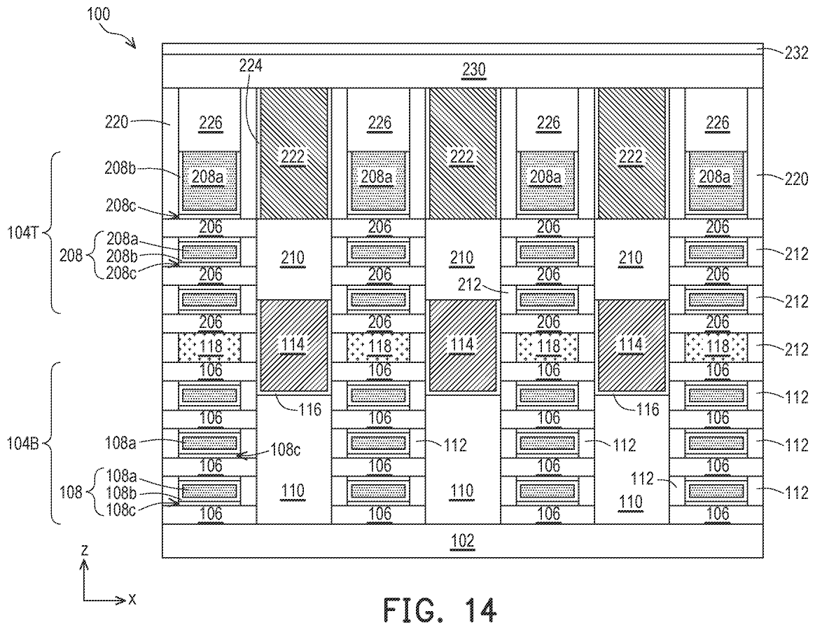

Referring to FIGS. 6B and 14, at operation 330, the method 300 forms S/D contacts 222, 224 over the first and second S/D features by a proper method, such as a procedure that includes patterning, deposition and CMP process. At operation 332, the method 300 may form the SAC features 226 self-aligned with the gate stacks 208 by a method, such as a procedure that includes etch to recess the gate stacks, depositing one or more dielectric material, and performing a CMP process. The method 300 may perform other operations to complete fabrication of the IC structure 100. Additional processing is contemplated by the present disclosure. Additional operations can be provided before, during, and after method 300, and some of the operations described can be moved, replaced, or eliminated for additional embodiments of method 300. For example, interconnect structure 230 may be further formed to couple various devices into an integrated circuit, and other feature such as a bonding layer 232 may be further formed on the interconnect structure to provide a bonding surface. In some embodiments, the interconnect structure 230 includes contacts, vias and metal lines distributed in multiple metal layers. In the copper interconnect, the conductive features include copper and may further include a barrier layer. The copper interconnect structure is formed by a damascene process. A damascene process includes depositing an ILD layer; patterning the ILD layer to form trenches; depositing various materials (such as a barrier layer and copper); and performing a CMP process. A damascene process may be a single damascene process or a dual damascene process. The deposition of the copper may include PVD to form a seed layer and plating to form bulk copper on the copper seed layer. Other metals, such as ruthenium, cobalt, tungsten or aluminum, may be used to form to form the interconnection structure.

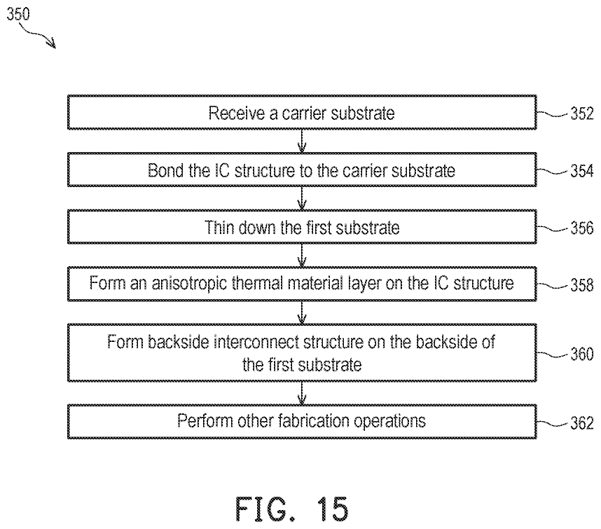

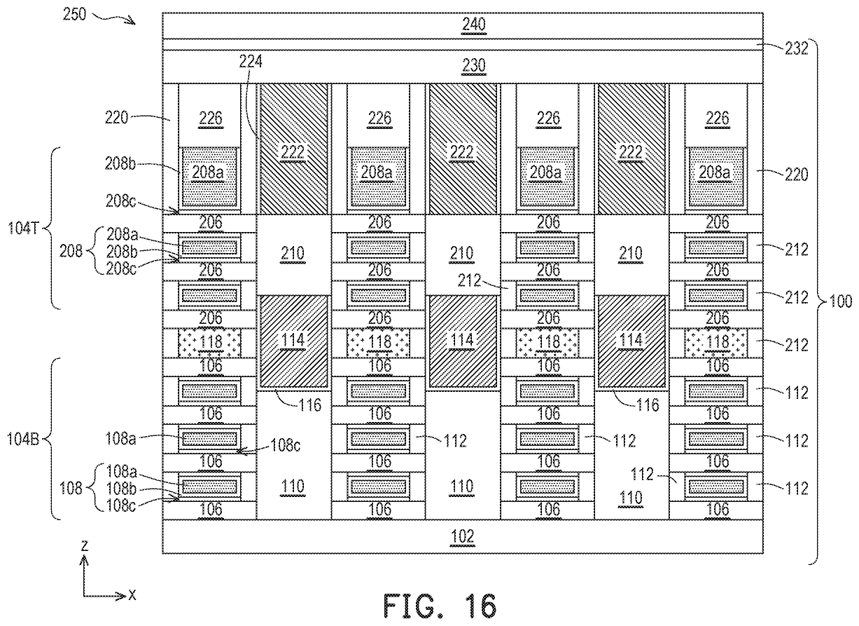

Such formed IC structure 100 is further bonded to a carrier substrate and incorporated with an anisotropic thermal dissipation material layer by the disclosed method. This is further described in detail with reference to FIGS. 15, 16, 17, 18 and 19 according to some embodiments. FIG. 15 is a flowchart of a method 350, FIGS. 16, 17, 18 and 19 are sectional views of an IC structure (or workpiece) 250 at various fabrication stages constructed according to some embodiments.

Referring to FIGS. 15 and 16, the method 350 proceeds to receive or provide a carrier substrate 240 at block 352. In some embodiments, the carrier substrate (or second substrate) 240 is a dielectric substrate such as a silicon nitride substrate, a silicon oxide substrate, or an aluminum oxide substrate. In some embodiments, the carrier substrate 240 is a semiconductor substrate such as a silicon substrate or alternatively a substrate with other suitable material(s). In yet other embodiments, the carrier substrate 240 is a semiconductor substrate with various devices formed thereon.

Still referring to FIGS. 15 and 16, at operation 354, the method 350 bonds the carrier substrate 240 to the frontside of the IC structure 100 (formed by the method 300 in FIGS. 6A and 6B, as illustrated in FIG. 14) such that the carrier substrate 240 is bonded to the bonding layer 232 of the IC structure 100, resulting in a bonded IC structure 250. In some embodiments, the carrier substrate 240 further includes various devices formed thereon; an interconnect structure formed on the corresponding devices; and a passivation layer formed on the interconnect structure. In furtherance of the embodiments, the carrier substrate 240 is bonded to the IC structure 100 in a frontside-to-frontside bonding mode such the IC structure 100 and the carrier substrate 240 are electrically connected through the bonding interface with a hybrid bonding structure, resulting in a bonded IC structure 250.

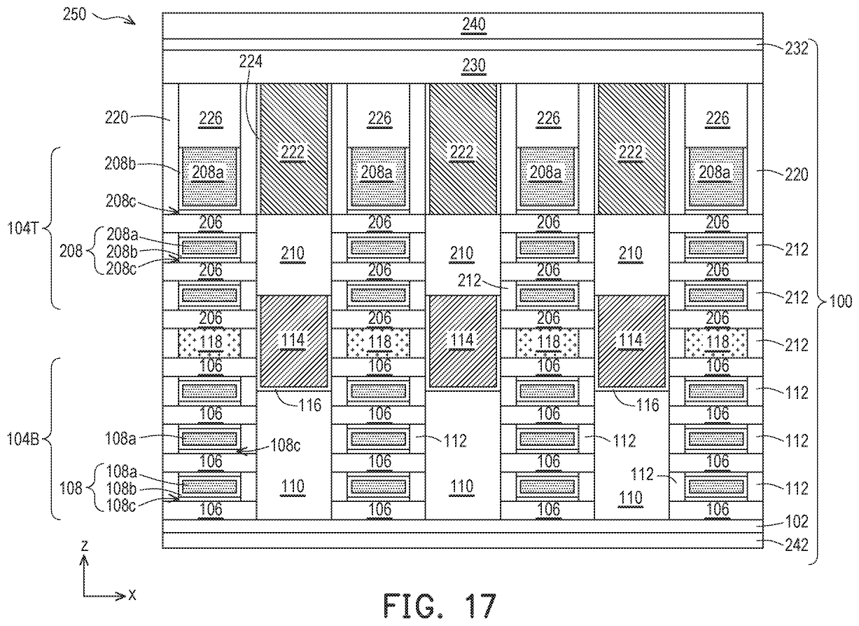

Referring to FIGS. 15 and 17, after bonding, the method 350 proceeds to an operation 356 to thins down the first substrate 102 from the backside. In some embodiments, the operation 356 includes performing a grinding process to reduce the thickness of the first substrate 102 and performing a chemical mechanical polishing (CMP) process to planarize the surface.

Still referring to FIGS. 15 and 17, at operation 358, an anisotropic thermal dissipation material layer 242 is formed on the backside of the first substrate 102 by a suitable method. In some embodiments, the anisotropic thermal dissipation material layer 242 may be a liquid crystal material, such as those described in FIG. 3A. The anisotropic thermal dissipation material layer 242 of a liquid crystal material is formed by a suitable method, such as the method described in FIGS. 4A through 4E.

In some embodiments, the anisotropic thermal dissipation material layer 242 may be a polymeric material such as those described in FIGS. 1, and 2C-2E. The anisotropic thermal dissipation material layer 242 of a polymer is formed on an IC structure by a suitable method. In furtherance of the embodiments, the first substrate 102 includes a dielectric surface layer (or simply dielectric layer) of one or more dielectric material disposed on the backside, such as dielectric surface layer 26 of silicon oxide in FIG. 2A or dielectric surface layer 28 of silicon nitride or silicon oxycarbonitride in FIG. 2B. The dielectric surface layer is formed by a suitable method, such as chemical vapor deposition (CVD). In this case, the operation 358 further includes depositing a dielectric surface layer on the backside of the first substrate 102. The dielectric surface layer further includes chemical groups (such as OH groups or NH₂ groups) intrinsically present or introduced by treatment.

In some embodiments, the first substrate 102 includes a dielectric surface layer of silicon oxide having OH groups, which are intrinsically present on the surface. The OH groups on the dielectric surface layer of silicon oxide chemically react with the chemical group R of the tapered bottlebrush polymer 20, thereby forming chemical bonds and immobilizing the tapered bottlebrush polymer 20 on the first substrate 102. In some embodiments, the dielectric surface layer of silicon oxide is further treated to introduce OH groups to the dielectric surface layer 26 using a proper treatment, such as ozone or hydrogen peroxide treatment. For example, the IC structure 250 is placed in an ozone or hydrogen peroxide environment with an elevated temperature for a certain duration, thereby forming a silicon oxide layer on the backside surface of the first substrate 102 before forming the anisotropic thermal dissipation material layer 242 on the first substrate 102. In this case, the operation 358 further includes step to performing a treatment to the dielectric surface layer using ozone or hydrogen peroxide.

In some embodiments, the first substrate 102 includes a dielectric surface layer of silicon nitride or silicon oxycarbonitride having NH₂ groups, which are intrinsically present on the surface. The NH₂ groups on the dielectric surface layer of silicon nitride or silicon oxycarbonitride chemically react with the chemical group R of the tapered bottlebrush polymer 20, thereby forming chemical bonds and immobilizing the tapered bottlebrush polymer 20 on the first substrate 102.

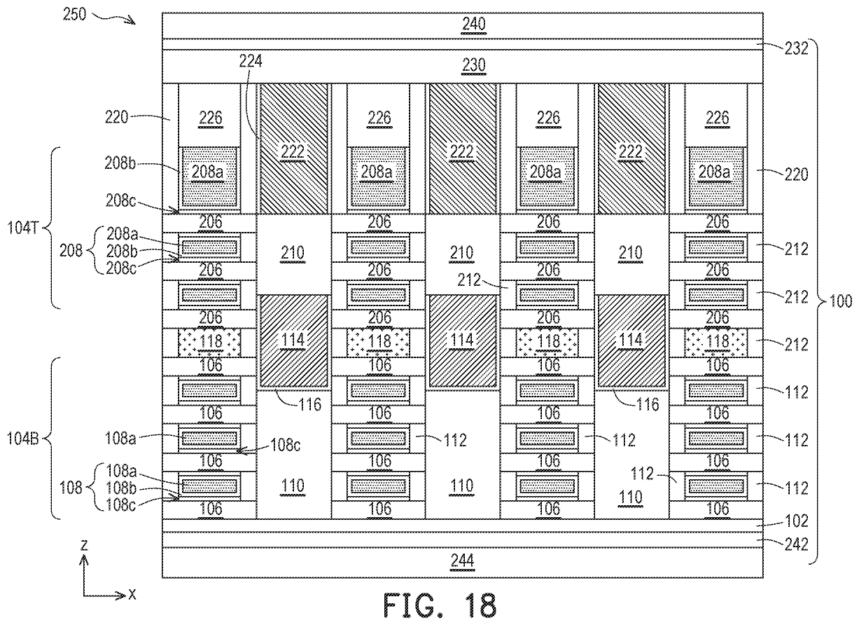

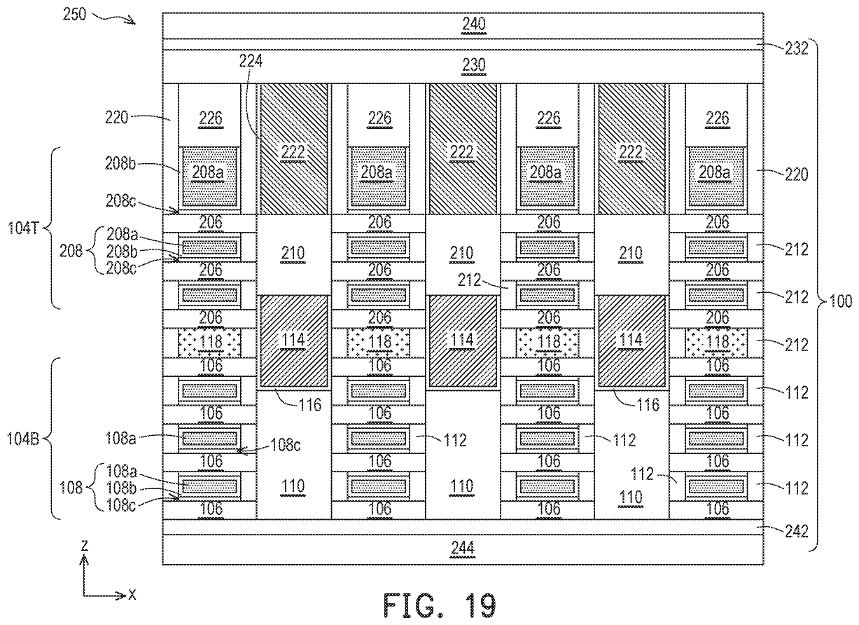

Referring to FIGS. 15 and 18, at operation 360, a backside interconnect structure 244 may be formed on the backside of the first substrate 102, such as over the anisotropic thermal dissipation material layer 242. In some embodiments, the backside interconnect structure 244 is configured to couple to the CFETs on the frontside of the first substrate 102. The backside interconnect structure 244 includes various conductive features, such as metal lines and metal vias distributed through one or more layers. In some embodiments, the backside vias are formed through the anisotropic thermal dissipation material layer 242 to be electrically coupled with CFETs.

In some alternative embodiments, the operation 356 thins down the first substrate 102 from the backside such that the CFETs are exposed from the backside. In this case, the anisotropic thermal dissipation material layer 242 is formed on the backside of the IC structure and is configured approximate to the CFETs for efficient thermal dissipation, as illustrated in FIG. 19. Other structures or features, such as the backside interconnect structure 244, may be formed on the backside the IC structure 100 and disposed on the anisotropic thermal dissipation material layer 242. The method 350 may include other fabrication operations 362 before, during or after the operations described above. The disclosed IC structure 250 provides a mechanism of laterally transferring the heat along a direction in parallel with the surface of the substrate 102, such as along X direction, thereby effectively dissipating the heat and reducing the thermal energy generated from the IC devices, such as CFETs.

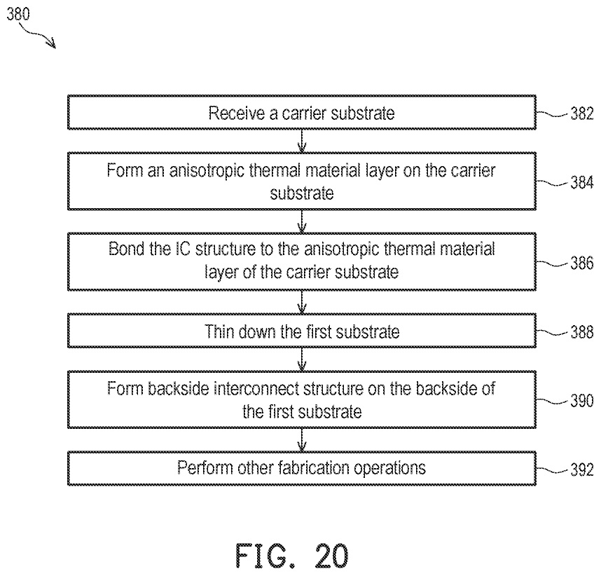

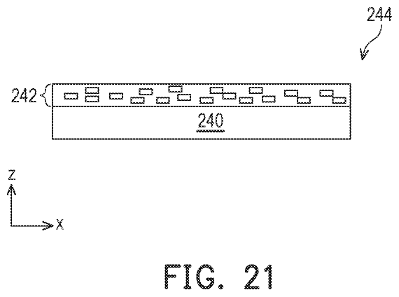

In some embodiments, the IC structure can be formed differently in structure and method, as illustrated in FIGS. 20 through 23. FIG. 20 is a flowchart of a method 380, FIGS. 21, 22 and 23 are sectional views of an IC structure (or workpiece) 280 at various fabrication stages constructed according to some embodiments.

Referring to FIGS. 20 and 21, the method 380 begins at an operation 382, a carrier substrate 240 is received or provided. In some embodiments, the carrier substrate (or second substrate) 240 is a dielectric substrate such as a silicon nitride substrate, a silicon oxide substrate, or an aluminum oxide substrate. In some embodiments, the carrier substrate 240 is a semiconductor substrate such as a silicon substrate or alternatively a substrate with other suitable material(s).

Still referring to FIGS. 20 and 21, the method 380 proceeds to an operation 384. At the operation 384, an anisotropic thermal dissipation material layer 242 is formed on the carrier substrate 240, thereby forming a carrier substrate structure 246. The process to form the anisotropic thermal dissipation material layer 242 on the carrier substrate 240 can be any suitable method, such as the method described in FIGS. 4A through 4E. In some embodiments, the anisotropic thermal dissipation material layer 242 can be a polymeric material or a liquid crystal material, such as those described in FIGS. 1, 2C-2E, and 3A.

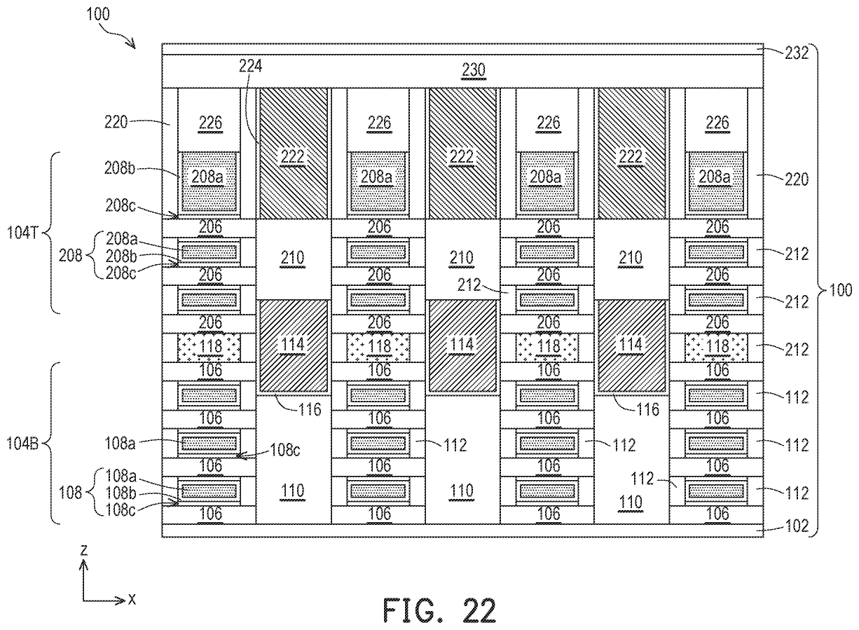

Referring to FIGS. 20 and 22, the method 380 proceeds to an operation 386 to thin down the first substrate 102 of the IC structure 100 (formed by the method 300 in FIGS. 6A and 6B, as illustrated in FIG. 14) from the backside. In some embodiments, the thin-down process includes grinding and a CMP process. In some embodiments, the thin-down process continues until the CFETs of the IC structure 100 are exposed from the backside.

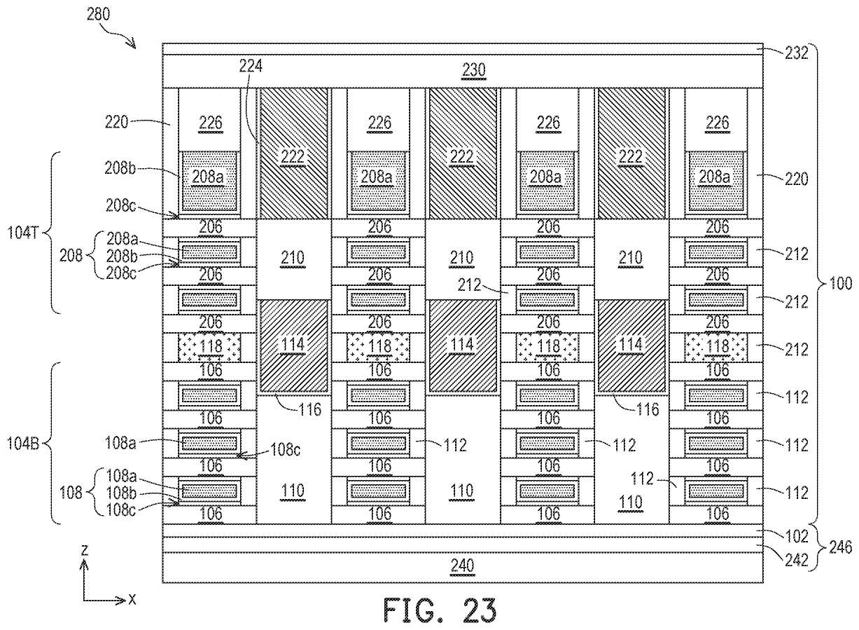

Referring to FIGS. 20 and 23, at operation 388, the method 380 bonds the carrier substrate structure 246 to the IC structure 100 in a frontside-to-backside bonding mode such that the anisotropic thermal dissipation material layer 242 is bonded to the backside of the substrate 102 of the IC structure 100, resulting in a bonded IC structure 280. The anisotropic thermal dissipation material layer 242 is similar to the anisotropic thermal dissipation material layer 242 in FIGS. 17-19 in terms of composition, configuration and formation.

The method 350 may include other fabrication operations 390 before, during or after the operations described above. For example, at operation 390, the IC structure 280 is stacked to another IC structure (or bonded to another substrate) and is further sealed in a same packaging structure by a 2.5D or 3D IC packaging structure.

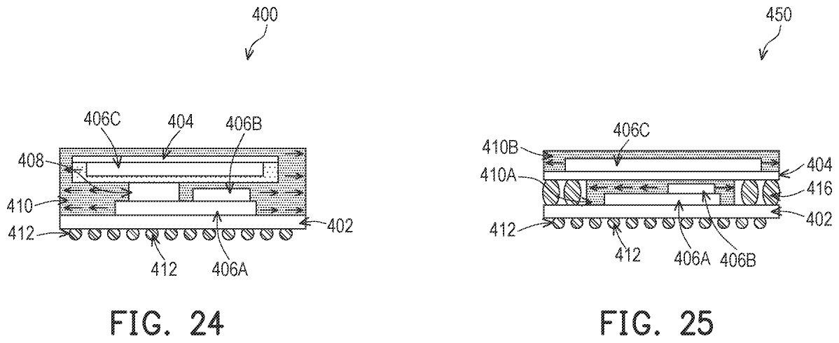

The anisotropic thermal dissipation material may be incorporated into other IC structures, such as a 2.5D or 3D IC packaging structure, as illustrated in FIGS. 24 and 25. FIGS. 24 and 25 are sectional views of IC structures 400 and 450, respectively, constructed according to various embodiments.

Referring to FIG. 24, the IC structure 400 includes substrates 402 and 404. In some embodiments, the substrate 402 (or the substrate 404) is a dielectric substrate such as a silicon nitride substrate, a silicon oxide substrate, or an aluminum oxide substrate. In some embodiments, the substrate 402 (or the substrate 404) is a semiconductor substrate such as a silicon substrate or alternatively a substrate with other suitable material(s). In yet some embodiments, the substrate 402 (or the substrate 404) is an IC structure having various IC devices (such as FETs or CFETs) formed on the corresponding substrate; an interconnect structure formed on the devices; and a passivation structure formed on the interconnect structure.

The IC structure 400 further includes various IC chips (or IC die) 406 configured between the substrates 402 and 404. One or more of the IC chips 406 has a structure as the IC structure 100 in FIG. 19 or 23. Those IC chips 406 are configured laterally on the substrate or vertically in stacks or combinations thereof. For example, the IC chips 406 includes three IC chips 406A, 406B and 406C. However, this only illustrates a particular example. The IC structure 400 may include any proper number of IC chips 406, such as 4 or 5 IC chips 406. The IC chips 406 may be any suitable chips, such as memory chips, central processing unit (CPU) chips, graphic processing unit (GPU) chips, input/output (I/O) chips, or combinations thereof. For example, the IC chips 406 includes an IC chip 406A as a CPU chip, an IC chip 406B as a memory chip, and an IC chip 406C as an I/O chip, collectively referred to as IC chips 406. Those IC chips 406 are electrically connected and integrated into an integrated circuit. The electrical connections among those IC chips 406 are achieved through any suitable structure, such as flip-chip, hybrid bonding, controlled collapse chip connection (C4), through substrate vias (TSVs) or combinations thereof.

Those IC chips 406 are integrated in any proper configuration. For example, the IC chip 406B is stacked on the IC chip 406A to form a chip stack, and the IC chip 406C is configured over the IC chips 406A and 406B. In some embodiments, one or more spacer 408 is incorporated, such as being vertically interposed between the IC chips 406A and 406C to support the IC chip 406C. The spacer 408 is a feature with proper shape and size to fit into the space between the IC chips 406A and 406C. The spacer 408 may be made of any proper material(s), such as metal.

The IC structure 400 is sealed in a same packaging using one or more scaling material, one or more underfill material, or a combination thereof. In the disclosed embodiments, the IC structure 400 includes a sealing material 410 that is an anisotropic thermal dissipation material, or a sealing material incorporated an anisotropic thermal dissipation material therein. For example, the sealing material 410 includes an anisotropic thermal dissipation polymer material dispersed therein. In another example, the scaling material 410 is an anisotropic thermal dissipation liquid crystal material with a scaling material dispersed therein.

Thus, the sealing material 410 provides an anisotropic thermal conductivity and is able to transfer heat directionally or laterally as illustrated by arrows in FIG. 24, in addition to the sealing effect. The IC structure 400 can effectively transfer heat directionally, dissipate heat, reduce heat accumulation and prevent thermal damage.

The IC structure 400 further includes conductive bumps 412 formed on the backside of the substrate 402 to provide electrical routing to a packaging substrate, another substrate, or a printed circuit board. In some embodiments, the conductive bumps 412 are solder balls. The conductive bumps 412 are electrically connected to the IC chips through proper structure or mechanism, such as TSVs formed in the substrate 402. In the disclosed embodiment, the IC chip 406A is bonded to the substrate 402, the IC chip 406B is stacked on the IC chip 406A. The IC chips 406A, 406B and the substrate 402 are sealed in a first sealing package. The IC chip 406C is bonded to the substrate 404 and are sealed in a second sealing package. The two sealing packages are further bonded and sealed to have a package in package (PIP) structure.

Referring to FIG. 25, the IC structure 450 includes substrates 402 and 404. In some embodiments, the substrate 402 (or the substrate 404) is a dielectric substrate such as a silicon nitride substrate, a silicon oxide substrate, or an aluminum oxide substrate. In some embodiments, the substrate 402 (or the substrate 404) is a semiconductor substrate such as a silicon substrate or alternatively a substrate with other suitable material(s). In yet some embodiments, the substrate 402 (or the substrate 404) is an IC structure having various IC devices (such as FETs or CFETs) formed on the corresponding substrate; an interconnect structure formed on the devices; and a passivation structure formed on the interconnect structure.

The IC structure 450 further includes various IC chips (or IC die) 406 configured between the substrates 402 and 404. Those IC chips 406 are configured laterally on the substrate or vertically in stacks or combinations thereof. For example, the IC chips 406 includes three IC chips 406A, 406B and 406C. However, this only illustrates a particular example. The IC structure 450 may include any proper number of IC chips 406, such as 4 or 5 IC chips 406. One or more of the IC chips 406 has a structure as the IC structure 100 in FIG. 19 or 23. The IC chips 406 may be any proper chips, such as memory chips, CPU chips, GPU chips, I/O chips, or combinations thereof. For example, the IC chips 406 includes an IC chip 406A as a CPU chip, an IC chip 406B as a memory chip, and an IC chip 406C as an I/O chip, collectively referred to as IC chips 406. Those IC chips 406 are electrically connected and integrated into an integrated circuit. The electrical connections among those IC chips 406 are achieved through any suitable structure, such as flip-chip, hybrid bonding, C4, TSVs or combinations thereof.

Those IC chips 406 are integrated in any proper configuration. For example, the IC chip 406B is stacked on the IC chip 406A to form a chip stack, and the IC chip 406C is bonded to and electrically connected to the substrate 404.

The IC structure 450 is sealed using one or more sealing material. In the disclosed embodiments, the IC structure 450 includes a sealing material 410 that is an anisotropic thermal dissipation material, or a sealing material incorporated an anisotropic thermal dissipation material therein. For example, the sealing material 410 includes an anisotropic thermal polymer material dispersed therein. In another example, the sealing material 410 is an anisotropic thermal liquid crystal material with a sealing material dispersed therein.

Thus, the sealing material 410 provides an anisotropic thermal conduction and is able to directionally transfer heat, such as laterally transferring heat as illustrated by arrows in FIG. 25, in addition to the sealing effect.

The IC structure 450 further includes conductive bumps 412 formed on the backside of the substrate 402 to provide electrical routing to a packaging substrate, another substrate, or a printed circuit board. In some embodiments, the conductive bumps 412 are solder balls. The conductive bumps 412 are electrically connected to the IC chips through proper structure or mechanism, such as TSVs formed in the substrate 402.

In the disclosed embodiment, the IC chip 406A is bonded to the substrate 402, the IC chip 406B is stacked on the IC chip 406A. The IC chips 406A, 406B and the substrate 402 are sealed in a first sealing package using a sealing material 410A. The IC chip 406C is bonded to the substrate 404 and are sealed in a second sealing package using a sealing material 410B. The second sealing package is stacked on the first sealing package on package (POP) structure. The IC chip 406C are electrically connected to the IC chips 406A and 406B through suitable mechanism. For example, the IC structure 450 further includes conductive bumps 416 formed between the substrates 402 and 404 to provide electrical routing therebetween and further to the IC chips 406. For example, the substrate 404 includes TSVs that electrically connect the conductive bumps 416 to the IC chip 406C, and the substrate 402 includes TSVs that electrically connect the conductive bumps 416 to the conductive bumps 412 and the IC chips 406A and 406B to the conductive bumps 412. An underfill material may be filled in the space between the substrates 402 and 404, thereby strengthening and sealing the conductive bumps 416.

In some embodiments, the sealing materials 410A and 410B are different. For example, the sealing material 410A includes an anisotropic thermal dissipation liquid crystal material while the sealing material 410B includes an anisotropic thermal dissipation polymer material. The IC structure 450 can effectively transfer heat directionally, dissipate heat, reduce heat accumulation and prevent thermal damage.

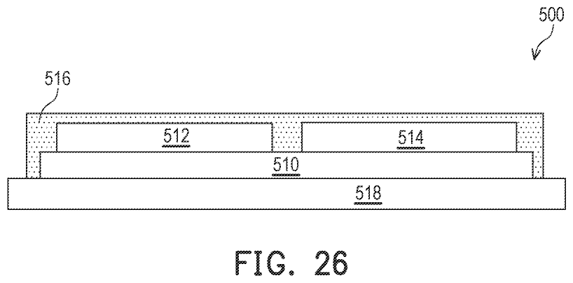

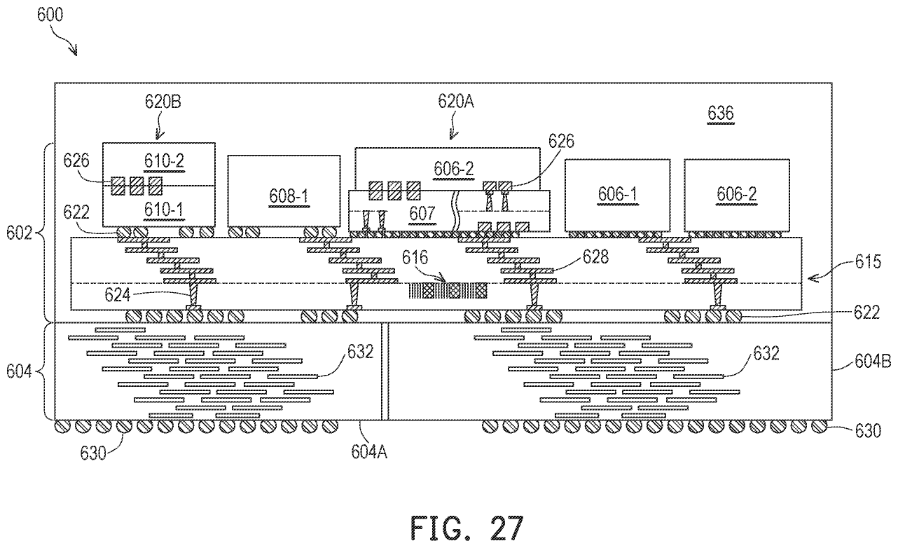

FIGS. 24 and 25 illustrate two embodiments, where the anisotropic thermal dissipation material is incorporated in 3DIC structure for directional thermal dissipation. However, it is not intended to be limiting. Other 3DIC structure with the anisotropic thermal dissipation material incorporated in the IC package are in the scope of the present disclosure. Other IC structure are further described below with reference to FIGS. 26 and 27 according to some embodiments.

FIG. 26 is a schematic view of an IC structure 500 constructed in accordance with some embodiments. The IC structure 500 includes a substrate 510, such as a semiconductor substrate or other suitable substrate; a first IC chip 512 and a second IC chip 514 formed over the substrate 510 in the same packaging 516. In some embodiments, at least one of the IC chips 512 and 514 has a structure as the IC structure 100 in FIG. 19 or 23. In some embodiments, the packaged IC structure is amounted and connected to a printed circuit board (PCB) 518 or other suitable circuit board. In some embodiments, the first IC chip 512 and the second IC chip 514 are formed directly on the same substrate 510 or formed at different level in a 3D structure but in the same packaging 516. In some embodiments, the first IC chip 512 is a CPU die and the second IC chip 514 is a memory chip. The IC chips 512 and 514 are co-packaged in a 3D IC structure, such as chip-on-wafer (COW), chip-on-wafer-on-substrate (CoWoS), and other suitable 3D structure. In the disclosed IC structure, each of the IC chips 512 and 514 further includes various active and passive electronic devices, such as FETs, FinFETs, and other multi-gate devices, such multi-gate devices include gate-all-around (GAA) devices. Particularly, the packaging 516 incorporates an anisotropic thermal dissipation material, such as an anisotropic thermal dissipation material dispersed with a scaling material. The IC structure 500 can effectively transfer heat directionally, such as transferring heat horizontally over the substrate 510.

FIG. 27 is a fragmentary cross-sectional view of the IC structure 600, in portion or entirety, that is provided by arranging a chipset using a combination of multichip packaging technologies, such as chip-on-wafer-on-substrate (CoWoS) packaging technology, system-on-integrated-chips (SoIC) multi-chip packaging technology, an integrated-fan-out (InFO) package, according to various aspects of the present disclosure. It is noted that the IC structure 100 in FIG. 27 is only for illustration and IC structure 600 may have other structure such as other 3D structure. The IC structure 600, which can be referred to as a 3D IC package and/or a 3D IC module, includes a CoW structure 602 attached to a substrate 604 (e.g., a package substrate), which includes a package component 604A and a package component 604B in the depicted embodiment. CoW structure 602 includes a chipset (e.g., a core chip 606-1, a core chip 606-2, photonic chip 607, a memory chip 608-1, a memory chip 608-2, an input/output (I/O) chip 610-1, and an I/O chip 610-2 electrically connected to each other) attached to an interposer 615. The chipset is arranged into at least one chip stack, such as a chip stack 620A and a chip stack 620B. Chip stack 620A includes core chip 606-2 and photonic chip 607, and chip stack 620B includes I/O chip 610-1 and I/O chip 610-2. In the depicted embodiment, chips of chip stack 620A and chip stack 620B are directly bonded face-to-face and/or face-to-back to provide SoIC packages of multichip package. In some embodiments, a chip stack of multichip package includes a combination of chip types, such as a core chip having one or more memory chips disposed thereover. FIG. 27 has been simplified for the sake of clarity to better understand the inventive concepts of the present disclosure. Additional features can be added in multichip package, and some of the features described below can be replaced, modified, or eliminated in other embodiments of multichip package.

Core chip 606-1 and core chip 606-2 are central processing unit (CPU) chips and/or other chips. In some embodiments, core chip 606-1 is a CPU chip that forms at least a portion of CPU cluster, and core chip 606-2 is a GPU chip. In some embodiments, core chip 606-1 and core chip 606-2, or combinations thereof represent a stack of CPU dies, which can be bonded and/or encapsulated in a manner that provides a CPU package and/or a CPU-based SoIC package. In some embodiments, core chip 606-1 and core chip 606-2, or combinations thereof represent a stack of dies, which can be bonded and/or encapsulated in a manner that provides a GPU package and/or a SoIC package (e.g., a GPU-based SoIC package). In some embodiments, core chip 606-1, core chip 606-2, or combinations thereof represent a stack of CPU dies, which can be bonded and/or encapsulated in a manner that provides a core package and/or a core-based SoIC package. In some embodiments, core chip 606-1, core chip 606-2, or combinations thereof are SoCs.

Memory chip 608-1 and memory chip 608-2 are high bandwidth memory (HBM) chips, a graphics double-data rate (GDDR) memory chips, dynamic random-access memory (DRAM) chips, static random-access memory (SRAM) chips, magneto-resistive random-access memory (MRAM) chips, resistive random-access memory (RRAM) chips, other suitable memory chips, or combinations thereof. In some embodiments, memory chip 608-1 and memory chip 608-2 are HBM chips that form at least a portion of the memory device. In some embodiments, memory chip 608-1 and memory chip 608-2 are a GDDR memory chips that form at least a portion of the memory device. In some embodiments, memory chip 608-1 is an HBM chip and memory chip 608-2 is a GDDR memory chip, or vice versa, that form at least a portion of the memory device. In some embodiments, memory chip 608-1 and/or memory chip 608-2 represent a stack of memory dies, which can be bonded and/or encapsulated in a manner that provides a memory package and/or a memory-based SoIC package. The memory package may be an HBM package (also referred to as an HBM cube) or a GDDR memory package.

Core chip 606-1, core chip 606-2 and photonic chip 607 (and thus chip stack 620A), memory chip 608-1, memory chip 608-2, and I/O chip 610-1 and I/O chip 610-2 (and thus chip stack 620B) are attached and/or interconnected to interposer 615. Interposer 615 is attached and/or interconnected to substrate 604. Various bonding mechanisms can be implemented in multichip package, such as electrically conductive bumps 622 (e.g., metal bumps), through semiconductor vias (TSVs) 624, bonding pads 626, or combinations thereof. For example, electrically conductive bumps 622 physically and/or electrically connect core chip 606-1, photonic chip 607 (and thus chip stack 620A), memory chip 608-1, memory chip 608-2, and I/O chip 610-1 (and thus chip stack 620B) to interposer 615. Electrically conductive bumps 622 and TSVs 624 physically and/or electrically connect interposer 615 to substrate 604. TSVs 624 of interposer 615 are electrically connected to electrically conductive bumps 622 of chips and/or chip stacks of CoW structure 602 through electrically conductive routing structures (paths) 628 of interposer 615. Bonding pads 626 physically and/or electrically connect photonic chip 607 and core chip 606-2 of chip stack 620A and I/O chip 610-1 and I/O chip 610-2 of chip stack 620B. Also, dielectric bonding layers adjacent to bonding pads 626 can physically contact photonic chip 607 and core chip 606-2 of chip stack 620A and/or I/O chip 610-1 and I/O chip 610-2 of chip stack 620B. In some embodiments, electrically conductive bumps 622 that connect chips and/or chip stacks to interposer 615 may be micro-bumps, while electrically conductive bumps 622 that connect interposer 615 to substrate 604 may be controlled collapse chip connections (referred to as C4 bonds) (e.g., solder bumps and/or solder balls). In some embodiments, at least one of those IC chips has a structure as the IC structure 100 in FIG. 19 or 23.

In some embodiments, substrate 604 is a package substrate, such as coreless substrate or a substrate with a core, that may be physically and/or electrically connected to another component by electrical connectors 630. Electrical connectors 630 are electrically connected to electrically conductive bumps 622 of interposer 615 through electrically conductive routing structures (paths) 632 of substrate 604. In some embodiments, package component 604A and package component 604B are portions of a single package substrate. In some embodiments, package component 604A and package component 604B are separate package substrates arranged side-by-side. In some embodiments, substrate 604 is an interposer. In some embodiments, substrate 604 is a printed circuit board (PCB).

In some embodiments, interposer 615 is a semiconductor substrate, such as a silicon wafer (which may generally be referred to as a silicon interposer). In some embodiments, interposer 615 is laminate substrate, a cored package substrate, a coreless package substrate, or the like. In some embodiments, interposer 615 can include an organic dielectric material, such as a polymer, which may include polyimide, polybenzoxazole (PBO), benzocyclobutene (BCB), other suitable polymer-based material, or combinations thereof. In some embodiments, redistribution lines (layers) (RDLs) can be formed in interposer 615, such as within the organic dielectric material(s) of interposer 615. RDLs may form a portion of electrically conductive routing structures 628 of interposer 615. In some embodiments, RDLs electrically connect bond pads on one side of interposer 615 (e.g., top side of interposer 615 having chipset attached thereto) to bond pads on another side of interposer 615 (e.g., bottom side of interposer 615 attached to substrate 604). In some embodiments, RDLs electrically connect bond pads on the top side of interposer 615, which may electrically connect chips of the chipset. In the disclosed embodiment, one or more deep trench capacitor 616 may be embedded in interposer 615.

In some embodiments, multichip package can be configured as a 2.5D IC package and/or a 2.5D IC module by rearranging the chipset, such that each chip is bonded and/or attached to interposer 615. In other words, the 2.5D IC module does not include a chip stack, such as chip stack 620A and chip stack 620B, and chips of the chipset are arranged in a single plane. In such embodiments, core chip 606-3 and I/O chip 610-2 are electrically and/or physically connected to interposer by electrically conductive bumps 622.

Particularly, the IC structure 600 is sealed in a package using a scaling material 636. In the present embodiment, the sealing material 636 includes an anisotropic thermal dissipation material described above. The IC structure 600 with the anisotropic thermal dissipation material in the sealing package provides a mechanism to effectively transfer heat directionally, such as transferring heat horizontally over the substrate 604.

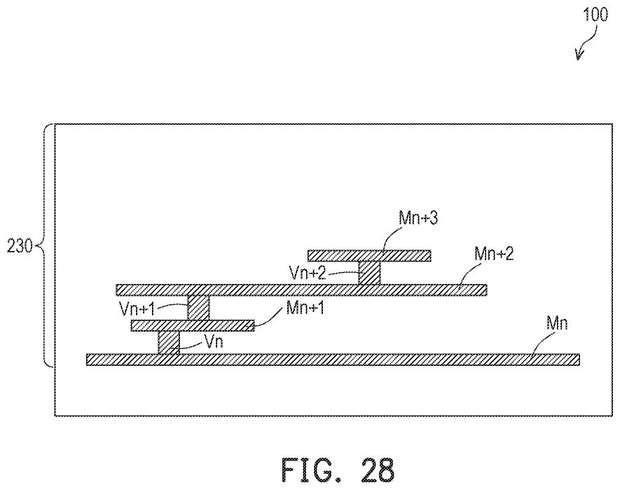

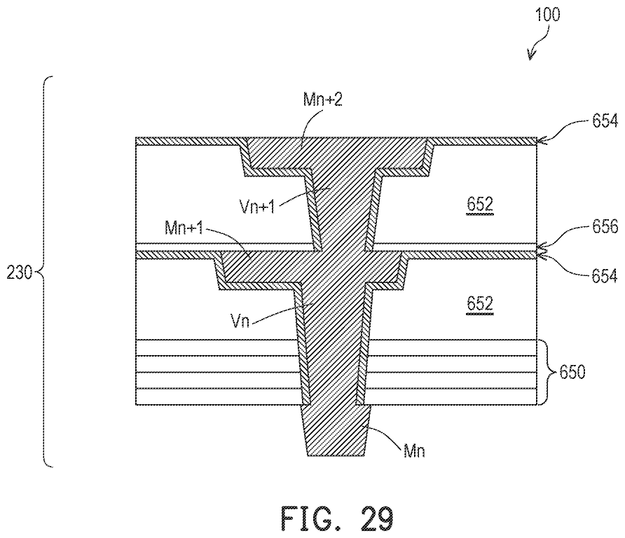

FIG. 28 is a sectional view of an IC structure 100, in portion, constructed in accordance with some embodiments. FIG. 29 is a sectional view of an IC structure 100, in portion, constructed in accordance with some embodiments. The IC structure 100 is similar to the IC structure 100 of FIG. 5. However, only a portion of the interconnect structure 230 in the IC structure 100 is illustrated in FIGS. 28 and 29.

Referring to FIG. 28, the IC structure 100, such as the IC structure 100 in FIG. 5, includes an interconnect structure 230 formed on CFETs and coupled the CFETs and other devices into an integrated circuit. The interconnect structure 230 includes metal lines distributed among a plurality of metal layers, such as metal lines M1 in the first metal layer, metal lines M2 in the second metal layers over the first metal layer, . . . , metal lines Mn in the nth metal layer, metal lines Mn+1 in the (n+1)^{th} metal layer over the nth metal layer, . . . , and so on. Metal lines in adjacent metal layers are connected through via features, such as V1, V2, . . . , Vn, . . . , and so on, as illustrated in FIG. 28.

The interconnect structure 230 is further described with reference to FIG. 29. In FIG. 29, the metal line Mn, Mn+1, and Mn+2, and the vias Vn and Vn+1 are illustrated. The metal lines and vias are formed in interlayer dielectric (ILD) layers 652. The metal lines and vias may include metal, metal alloy, other conductive materials or a combination thereof. For example, the metal lines and vias may include copper, aluminum, copper alloy, nickel, cobalt, tungsten, or a combination thereof. The ILD layers 652 include one or more dielectric materials, such as silicon oxycarbide (SiOC), silicon oxide (SiOx), organosilicate glass (SiCOH), SiCNH, low-k dielectric material, or a combination thereof. The metal lines and vias are formed by any suitable method, such as a damascene process, such as dual damascene process and single damascene process. In a damascene process, an ILD layer is deposited and is patterned to form trenches; one or more conductive material is deposited to fill in the trenches; and a CMP process is applied to remove the excessive metal and planarize the top surface.

The interconnect structure 230 may further include one or more etch stop layer (such as etch stop layers 650 and 656) to stop etching during the process to form metal lines and vias, such as in a damascene process. An etch stop layer (such as 650, or 654) includes one or more dielectric material different from that of the ILD layer to achieve etch selectivity and effectively stop the etching process applied to the ILD layer. An etch stop layer may include SiCO, AlOx, AlN, SiCON, SiCH, SiCOH, SiCNH, other suitable dielectric material, or a combination thereof. In some embodiments, each etch stop layer may include two or more dielectric films to strengthen the etch selectivity. For example, the etch stop layer 650 includes an AlN film, a SiCO film over the AlN film, an AlOx film over the SiCO film, and a another SiCO film over the AlOx film.

To prevent metal diffusion from the metal lines and vias to the ILD layers, a barrier layer 654 is further formed to surround the corresponding metal lines and vias. For example, after the trenches are formed in the ILD layer during a damascene process, the barrier layer is formed on sidewalls of the trenches (such as by deposition and plasma etching), and thereafter, the metal (or metal alloy) is deposited on the barrier layer to fill the trenches. In some embodiments, the barrier layer 654 may include AlN, AlOx, SiCN, SiOC, other dielectric material or a combination thereof.

Furthermore, the anisotropic thermal dissipation material may be incorporated into the ILD layers 652, the etch stop layers 650, 656, the barrier layers 654, or a subset of the above to enhance the thermal dissipation. For example, an anisotropic thermal dissipation material (such as an anisotropic thermal dissipation liquid crystal material or an anisotropic thermal dissipation polymer material described above) is incorporated in the ILD layers 652. As described above, those anisotropic thermal dissipation material is electrically insulating but thermally conductive, such formed ILD layer 652 (barrier layer 654, and/or etch stop layer 650/656) can effectively transfer heat directionally without interrupting the electrical isolation function of the ILD layer 652 (barrier layer 654, and/or etch stop layer 650/656).

The present disclosure provides an IC structure having CFET devices and an anisotropic thermal dissipation material layer, and a method making the same according to various embodiments. The anisotropic thermal dissipation material layer functions as directional thermal dissipation and may additionally function as sealing, barrier, isolation, stop etching stop, or a combination thereof. The disclosed IC structure can effectively transfer heat directionally, dissipate heat, reduce heat accumulation, prevent thermal damage, and enhance the performance and reliability of the IC structure.

In one example aspect, the present disclosure provides an integrated circuit (IC) structure. The IC structure includes a FET of a first type conductivity, a second FET of a second type conductivity opposite to the first type conductivity, and an anisotropic thermal dissipation structure disposed underlying the first FET. The second FET is stacked over the first FET along a first direction. The first FET further includes first channels vertically stacked along the first direction, the first channels longitudinally extending along a second direction that is perpendicular to the first direction; a first source and a first drain disposed on opposite sides of the first channels and contacting each of the first channels; and a first gate interposed between the first source and the first drain, and extending to wrap around each of the first channels. The second FET further includes second channels vertically stacked along the first direction, the second channels longitudinally extending along the second direction; a second source and a second drain disposed on opposite sides of the second channels and contacting each of the second channels; and a second gate interposed between the second source and the second drain, and extending to wrap around each of the second channels. The anisotropic thermal dissipation structure includes an anisotropic thermal dissipation material is electrically insulating and thermally conductive with a first thermal conductivity along the first direction and a second thermal conductivity along the second direction, and wherein the second thermal conductivity is substantially greater than the first thermal conductivity.

In another example aspect, the present disclosure provides an integrated circuit (IC) structure. The IC structure includes a first substrate with a first surface having a normal direction along a first direction; a first IC chip bonded to the first substrate; and a second IC chip electrically connected to the first IC chip. The first and second IC chips are sealed in a same package having a sealing material layer, and the sealing material layer includes a first anisotropic thermal dissipation material. The first anisotropic thermal dissipation material is thermally conductive with a first thermal conductivity along the first direction and a second thermal conductivity along a second direction being perpendicular to the first direction. The second thermal conductivity is substantially greater than the first thermal conductivity.

In yet another example aspect, the present disclosure provides a method of making an integrated circuit (IC) structure. The method includes forming a circuit structure having semiconductor devices on frontside of a substrate and an interconnect structure over the semiconductor devices; coating a solution to a backside of the substrate, the solution including a photosensitive material and a liquid crystal material; applying an electrical field to the solution; and curing the solution while the electrical field is applied to the solution.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. An integrated circuit (IC) structure, comprising:
a first field-effect transistor (FET) of a first type conductivity, wherein the first FET further includes
first channels vertically stacked along a first direction, the first channels longitudinally extending along a second direction that is perpendicular to the first direction,
a first source and a first drain disposed on opposite sides of the first channels and contacting each of the first channels, and
a first gate interposed between the first source and the first drain, and extending to wrap around each of the first channels;
a second FET of a second type conductivity opposite to the first type conductivity, wherein the second FET is stacked over the first FET along the first direction and further includes
second channels vertically stacked along the first direction, the second channels longitudinally extending along the second direction,
a second source and a second drain disposed on opposite sides of the second channels and contacting each of the second channels, and
a second gate interposed between the second source and the second drain, and extending to wrap around each of the second channels; and
an anisotropic thermal dissipation structure disposed underlying the first FET, wherein the anisotropic thermal dissipation structure includes an anisotropic thermal dissipation material is electrically insulating and thermally conductive with a first thermal conductivity along the first direction and a second thermal conductivity along the second direction, and wherein the second thermal conductivity is substantially greater than the first thermal conductivity.

2. The IC structure of claim 1, wherein the anisotropic thermal dissipation material includes an anisotropic thermal dissipation polymer.

3. The IC structure of claim 2, wherein the anisotropic thermal dissipation polymer is a tapered bottlebrush polymer.

4. The IC structure of claim 3, wherein
the IC structure includes a dielectric surface layer of silicon oxide (SiO₂) having OH chemical groups; and
the anisotropic thermal dissipation polymer includes chemical groups R chemically bonded with the OH chemical groups of the dielectric surface layer.

5. The IC structure of claim 3, wherein
the IC structure includes a dielectric surface layer of silicon nitride (SiN) having NH₂ chemical groups; and
the anisotropic thermal dissipation polymer includes chemical groups R chemically bonded with the NH₂ chemical groups of the dielectric surface layer.

6. The IC structure of claim 3, wherein
the IC structure includes a dielectric surface of silicon oxycarbonitride (SiOCN) having NH₂ chemical groups; and
the anisotropic thermal dissipation polymer includes chemical groups R chemically bonded with the NH₂ groups chemical groups of the dielectric surface.

7. The IC structure of claim 1, wherein the anisotropic thermal dissipation material includes an anisotropic thermal dissipation liquid crystal.

8. The IC structure of claim 7, wherein the anisotropic thermal dissipation material further includes a photoresist material mixed with the anisotropic thermal dissipation liquid crystal.

9. The IC structure of claim 1, further comprising an interconnect structure formed over the second FET and electrically connected to the first FET and the second FET, wherein the interconnect structure includes
an interlayer dielectric material (ILD) structure; and
metal lines distributed among multiple metal layers spaced along the first direction, the metal lines being embedded in the ILD structure, wherein the anisotropic thermal dissipation material is a first anisotropic thermal dissipation material, and wherein the ILD structure further includes a second anisotropic thermal dissipation material.

10. The IC structure of claim 9, wherein
the interconnect structure further includes a dielectric barrier layer disposed on sidewalls of the metal lines; and
the dielectric barrier layer includes a third anisotropic thermal dissipation material.

11. The IC structure of claim 10, wherein the ILD structure further includes a first ILD layer, a second ILD layer, and an etch stop layer disposed between the first and second ILD layers, and wherein the etch stop layer includes a fourth anisotropic thermal dissipation material.

12. The IC structure of claim 1, further comprising
an IC chip electrically connected to the first and second FETs, wherein
the IC chip, the first FET and the second FET are sealed in a same package using a sealing material, and
the sealing material includes another anisotropic thermal dissipation material.

13. An integrated circuit (IC) structure, comprising:
a first substrate with a first surface having a normal direction along a first direction;
a first IC chip bonded to the first substrate; and
a second IC chip electrically connected to the first IC chip, wherein
the first and second IC chips are sealed in a same package having a sealing material layer, and
the sealing material layer includes a first anisotropic thermal dissipation material, wherein the first anisotropic thermal dissipation material is thermally conductive with a first thermal conductivity along the first direction and a second thermal conductivity along a second direction being perpendicular to the first direction, and wherein the second thermal conductivity is substantially greater than the first thermal conductivity.

14. The IC structure of claim 13, wherein the second IC chip is bonded to the first IC chip.

15. The IC structure of claim 13, further comprising:
a second substrate; and
a third IC chip bonded to the second substrate, wherein
the third IC chip is electrically connected with the first and second IC chips,
the second substrate, the first, second and third IC chips are sealed in a sealing package using a second sealing material, and
the second sealing material includes another anisotropic thermal dissipation material.

16. The IC structure of claim 13, wherein one of the first and IC chips includes
a first field-effect transistor (FET) of a first type conductivity, wherein the first FET further includes
first channels vertically stacked along the first direction, the first channels longitudinally extending along the second direction;
a first source and a first drain disposed on opposite sides of the first channels and contacting each of the first channels, and
a first gate interposed between the first source and the first drain, and extending to wrap around each of the first channels;
a second FET of a second type conductivity opposite to the first type conductivity, wherein the second FET further includes
second channels vertically stacked along the first direction, the second channels longitudinally extending along the second direction,
a second source and a second drain disposed on opposite sides of the second channels and contacting each of the second channels,
a second gate interposed between the second source and the second drain, and extending to wrap around each of the second channels; and
a second anisotropic thermal dissipation material disposed underlying the first FET.

17. The IC structure of claim 13, wherein the first anisotropic thermal dissipation material includes an anisotropic thermal dissipation polymer.

18. The IC structure of claim 17, wherein
the IC structure includes a dielectric surface layer of silicon nitride (SiN) having NH₂ chemical groups; and
the anisotropic thermal dissipation polymer includes chemical groups R chemically bonded with the NH₂ chemical groups of the dielectric surface layer.

19. A method of making an integrated circuit (IC) structure, comprising:
forming a circuit structure having semiconductor devices on frontside of a substrate and an interconnect structure over the semiconductor devices;
coating a solution to a backside of the substrate, the solution including a photosensitive material and a liquid crystal material;
applying an electrical field to the solution; and
curing the solution while the electrical field is applied to the solution.

20. The method of claim 19, wherein
the semiconductor devices include a complimentary field-effect transistor (CFET);
the curing the solution includes applying an ultraviolet (UV) radiation; and
the electrical field is applied such that the electrical field is in parallel with the substrate.
